(19) United States
(12) Patent Application Publication
(10) Pub. No.: US 2026/0343760 A1
(43) Pub. Date: Oct. 29, 2026

(54) ELECTRONIC DEVICE INCLUDING FLEXIBLE DISPLAY

(71) Applicant: Samsung Electronics Co., Ltd., Suwon-si (KR)

(72) Inventors: Soonwan CHUNG, Suwon-si (KR); Hyeonmin LEE, Suwon-si (KR); Junho LEE, Suwon-si (KR); Myunggwan PARK, Suwon-si (KR); Jeayou KIM, Suwon-si (KR)

(21) Appl. No.: 19/677,528

(22) Filed: May 14, 2026

Related U.S. Application Data
(63) Continuation of application No. PCT/KR2026/096215, filed on Apr. 23, 2026.

(30) Foreign Application Priority Data
Apr. 29, 2025 (KR) 10-2025-0056258
May 30, 2025 (KR) 10-2025-0071450
Feb. 5, 2026 (KR) 10-2026-0023628

(51) Int. Cl. H05K 5/02; H05K 5/03

(52) U.S. Cl. CPC H05K 5/0226; H05K 5/03

(57) ABSTRACT

An electronic device is provided. The electronic device includes a first housing, a second housing coupled to the first housing to be rotatable about a folding axis by using a hinge device, a flexible display disposed to be supported by the first housing and the second housing and including a plurality of layers, and a protective member including a first protective member disposed on a first inner portion of the first housing parallel to the folding axis and a second protective member disposed on a second inner portion of the second housing parallel to the folding axis, wherein the first protective member is spaced apart from a first edge of the flexible display facing the first inner portion by a predetermined distance, and wherein the second protective member is spaced apart from a second edge of the flexible display facing the second inner portion by the predetermined distance.

### CROSS-REFERENCE TO RELATED APPLICATIONS

This application is a continuation application, claiming priority under 35 U.S.C. § 365(c), of an International application No. PCT/KR2026/096215, filed on Apr. 23, 2026, which is based on and claims the benefit of a Korean patent application number 10-2025-0056258, filed on April 29, 2025, in the Ministry of Intellectual Property (MOIP), of a Korean patent application number 10-2025-0071450, filed on May 30, 2025, in the Ministry of Intellectual Property (MOIP), and of a Korean patent application number 10-2026-0023628, filed on Feb. 5, 2026, in the Ministry of Intellectual Property (MOIP), the disclosure of each of which is incorporated by reference herein in its entirety.

### TECHNICAL FIELD

The disclosure relates to an electronic device including a flexible display.

### BACKGROUND ART

Electronic devices are gradually becoming slimmer and are being improved to increase rigidity thereof, to enhance design aspects, and to differentiate functional elements thereof. Electronic devices are gradually evolving from a uniform rectangular shape to diverse shapes. An electronic device may have a transformable structure that is convenient to carry and enables use of a large-screen display. For example, as part of the transformable structure, an electronic device may include foldable housings that operate by folding or unfolding relative to one another. Such an electronic device may require improved durability capable of withstanding external impacts and a protective structure for improving surface quality of a flexible display during folding operations.

The above information is presented as background information only to assist with an understanding of the disclosure. No determination has been made, and no assertion is made, as to whether any of the above might be applicable as prior art with regard to the disclosure.

### DISCLOSURE OF INVENTION

### Technical Problem

A foldable electronic device may include a hinge device (e.g., a hinge structure or a hinge module), and a first housing and a second housing foldably connected to each other through the hinge device. Such a foldable electronic device may be operated in an in-folding and/or out-folding manner as the first housing is rotated with respect to the second housing through the hinge device within a range of 0 degrees to 360 degrees. The foldable electronic device may include a flexible display disposed to be supported at least partially by the first housing and the second housing in an unfolded state. This flexible display may include multiple layers (e.g., window layer, polarizer (POL), polymer layer, or at least one functional layer) disposed on the top surface and/or the bottom surface relative to the display panel.

In a foldable electronic device, a protective cover (e.g., a decorative cover or a protective frame) disposed so as to prevent an edge (e.g., a periphery) of a flexible display from being visible from the outside may be omitted. Omission of the protective cover may help provide a relatively expanded display region in an electronic device having the same size. In the electronic device in which the protective cover is omitted, the flexible display may be disposed such that edges thereof are visible from the outside while being supported by the first housing and the second housing.

In the flexible display, according to a folding operation, interlayer slip may occur due to a plurality of layers that are attached to each other via an adhesive and/or an adhesive member. In consideration of such interlayer slip of the flexible display, the flexible display may be disposed to have a predetermined gap (e.g., a spaced arrangement) between an edge parallel to the folding axis and an inner surface of the first housing and/or the second housing. However, due to such a gap, a user may feel discomfort when using an electronic device including the flexible display. As a method for reducing such a gap, a method may be applied in which, after the flexible display is disposed to be supported by a housing, a filler (e.g., a resin or a molding material) is applied and cured. However, such a method may require processes of removing the filler entirely, then replacing components, and refilling the filler during maintenance of the electronic device. In addition, during maintenance of the electronic device, an expensive flexible display may be damaged by a filler attachment structure attached to a side surface portion of the flexible display in the process of removing the filler.

### Solution to Problem

Aspects of the disclosure are to address at least the above-mentioned problems and/or disadvantages and to provide at least the advantages described below. Accordingly, an aspect of the disclosure is to provide an electronic device including a flexible display that helps improve durability against external impacts by providing a protective structure for a side surface portion of the flexible display.

Another aspect of the disclosure is to provide an electronic device including a flexible display having a protective structure for improving surface quality in consideration of durability improvement and an amount of slip of the flexible display during folding.

Another aspect of the disclosure is to provide an electronic device including a flexible display having a protective structure for increasing productivity of the electronic device and reducing operational difficulty during maintenance of the electronic device.

Additional aspects will be set forth in part in the description which follows and, in part, will be apparent from the description, or may be learned by practice of the presented embodiments.

In accordance with an aspect of the disclosure, an electronic device is provided. The electronic device includes a first housing, a second housing coupled to the first housing to be rotatable about a folding axis by using a hinge device, a flexible display disposed to be supported by the first housing and the second housing and including a plurality of layers, and a protective member including a first protective member disposed on a first inner portion of the first housing parallel to the folding axis and a second protective member disposed on a second inner portion of the second housing parallel to the folding axis, wherein the first protective member is spaced apart from a first edge of the flexible display facing the first inner portion by a predetermined distance, and wherein the second protective member is spaced apart from a second edge of the flexible display facing the second inner portion by the predetermined distance.

In accordance with an aspect of the disclosure, a method of manufacturing an electronic device is provided. The method including inserting at least a portion of a dummy member including a cavity portion configured to form an empty space having a predetermined shape in interiors of first and second housings, pressurizing the first and second housings and the dummy member such that the first and second housings and the dummy member are in close contact with each other, injecting a filler into the first and second housings, curing the filler to form protective members, and separating the dummy member from the first and second housings, wherein the second housing is coupled to the first housing to be rotatable about a folding axis by using a hinge device, wherein the first and second housings are configured to support a flexible display including a plurality of layers, wherein the protective members include a first protective member disposed on a first inner portion of the first housing parallel to the folding axis, and a second protective member disposed on a second inner portion of the second housing parallel to the folding axis, wherein the first protective member is spaced apart from a first edge of the flexible display by a predetermined distance, and wherein the second protective member is spaced apart from a second edge of the flexible display by the predetermined distance.

### Advantageous Effects of Invention

An electronic device according to embodiments of the disclosure includes an improved protective structure for a side surface portion of the flexible display, and such a protective structure help improve durability against external impacts.

In addition, the electronic device according to embodiments includes a protective structure for improving durability of the flexible display. Such a protective structure help improve surface quality in consideration of an amount of slip of the flexible display during folding of the electronic device.

In addition, the electronic device according to embodiments includes a protective structure spaced apart from the flexible display. Such a protective structure help increase productivity of the electronic device and reduce operational difficulty during maintenance of the electronic device.

In addition to the above, various effects that is directly or indirectly identified through this document is provided.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1A is a front perspective view illustrating an electronic device in a flat or unfolded state according to an embodiment of the disclosure;

FIG. 1B is a front view illustrating of an electronic device in an unfolded state according to an embodiment of the disclosure;

FIG. 1C is a rear view illustrating an electronic device in an unfolded state according to an embodiment of the disclosure;

FIG. 2A is a perspective view an electronic device in a folded state according to an embodiment of the disclosure;

FIG. 2B is a perspective view illustrating an electronic device in an intermediate state according to an embodiment of the disclosure;

FIG. 3 is an exploded perspective view of an electronic device according to an embodiment of the disclosure;

FIG. 4A is an exploded perspective view of a flexible display according to an embodiment of the disclosure;

FIG. 4B is a view illustrating a configuration of a flexible display as viewed from a rear side according to an embodiment of the disclosure;

FIG. 5 is a cross-sectional view schematically illustrating an interlayer slip phenomenon occurring when a flexible display is folded according to an embodiment of the disclosure;

FIGS. 6A, 6B, 6C, 6D, 6E, 6F, 6G, 6H, 6I, and 6J are views illustrating protective members, as viewed along line 6-6 of FIG. 1A according to various embodiments of the disclosure;

FIG. 7 is a view illustrating a state in which a dummy member is coupled to a first housing and a second housing according to an embodiment of the disclosure;

FIG. 8 is a partial cross-sectional view taken along line 8-8 of FIG. 7, according to an embodiment of the disclosure;

FIG. 9 is a view illustrating a state in which a first housing and a second housing, to which a dummy member is coupled, are coupled to a jig according to an embodiment of the disclosure;

FIG. 10 is a partial cross-sectional view illustrating a state in which a filler constituting a protective member is filled, taken along line 8-8 of FIG. 7, according to an embodiment of the disclosure; and

FIG. 11 is a view illustrating a process of applying a protective member to a flexible display according to an embodiment of the disclosure.

The same reference numerals are used to represent the same elements throughout the drawings.

### MODE FOR THE INVENTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth^{®} chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

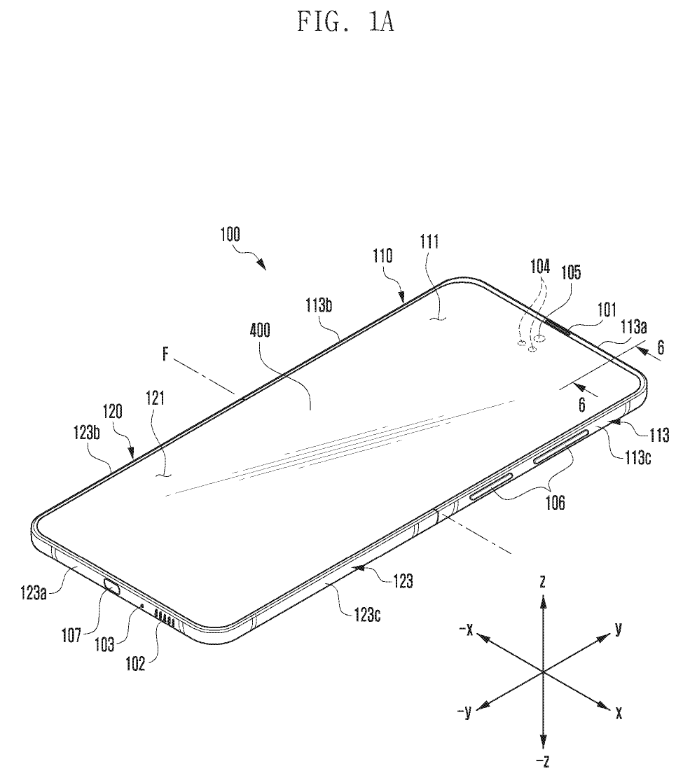

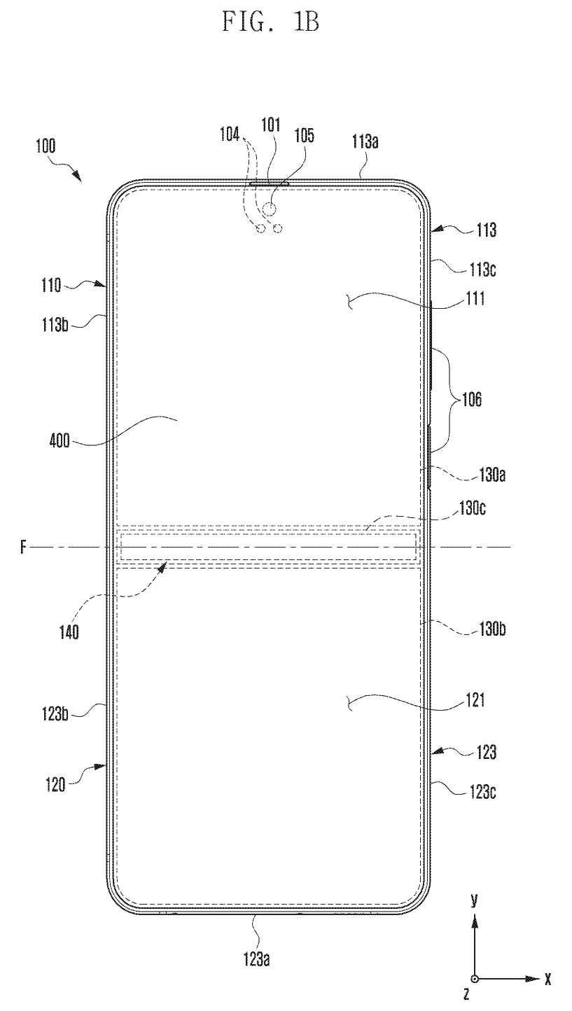

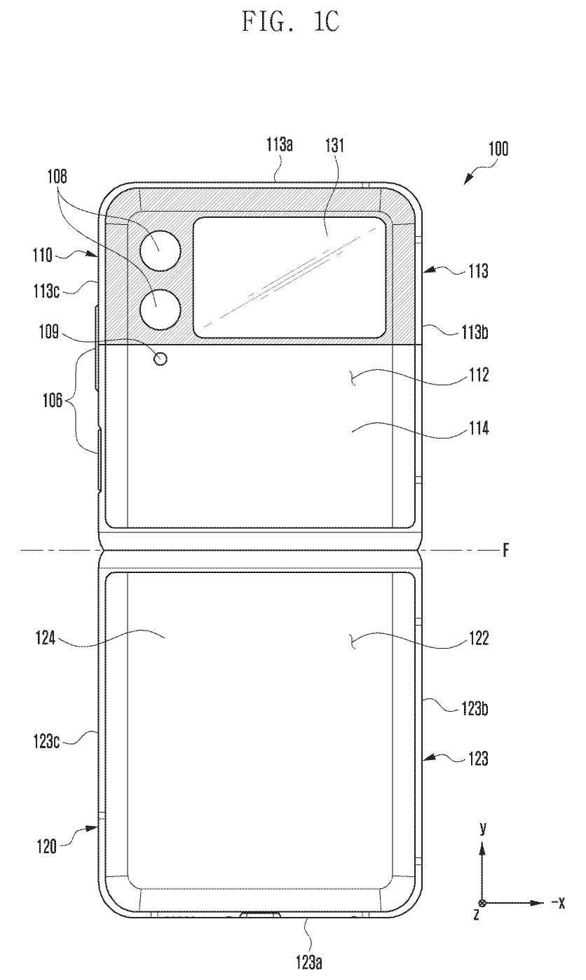

FIG. 1A is a perspective view illustrating an electronic device in an unfolded or flat state according to an embodiment of the disclosure.

FIG. 1B is a plan view illustrating a front surface of a foldable electronic device in the unfolded state according to an embodiment of the disclosure.

FIG. 1C is a rear view illustrating an electronic device in an unfolded state according to an embodiment of the disclosure.

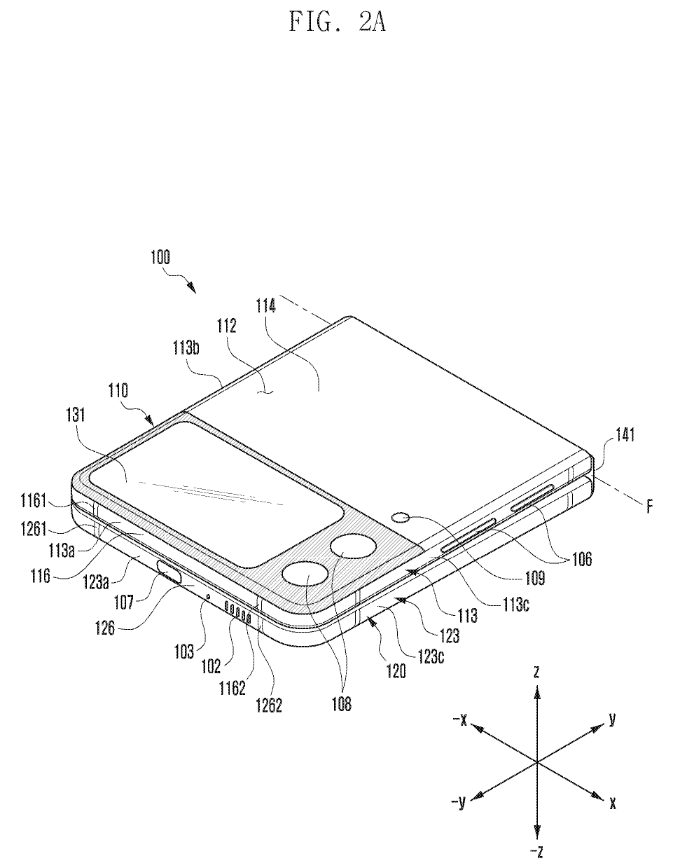

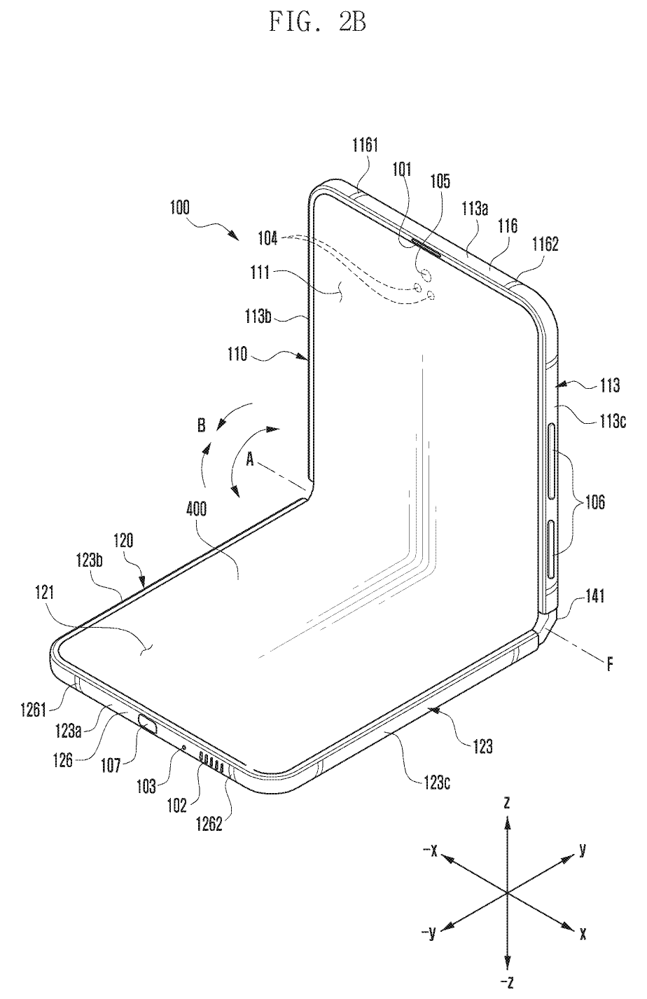

FIG. 2A is a perspective view illustrating an electronic device in a folded state according to an embodiment of the disclosure.

FIG. 2B is a perspective view illustrating an electronic device in an intermediate state according to an embodiment of the disclosure.

Referring to FIGS. 1A, 1B, 1C, 2A, an electronic device 100 may include first and second housings 110 and 120 coupled to be foldable relative to each other with respect to a hinge device (e.g., the hinge device 140 of FIG. 1B) (e.g., a foldable housing structure). In an embodiment, the hinge device (e.g., the hinge device 140 of FIG. 1B) may be disposed in the X -axis direction or disposed in the Y-axis direction. In an embodiment, the electronic device 100 may include a first display 400 (e.g., a flexible display, a foldable display, or a main display) disposed in a region (e.g., a recess) defined by the first and second housings 110 and 120. In an embodiment, the first housing 110 and the second housing 120 may be disposed on opposite sides of a folding axis F and may have shapes that are substantially symmetrical to each other with respect to the folding axis F. In an embodiment, the angle or distance between the first housing 110 and the second housing 120 may vary depending on the state of the electronic device 100. For example, the angle or distance between the first housing 110 and the second housing 120 depending on whether the electronic device is in the flat or unfolded state, the folded state, or the intermediate state.

In an embodiment, the first housing 110 may include, when the electronic device 100 is in the unfolded state, a first surface 111 facing a first direction (e.g., the front direction) (the z-axis direction) and a second surface 112 facing a second direction (e.g., the rear direction) (the -z-axis direction) opposite to the first surface 111. In an embodiment, the second housing 120 may include, when the electronic device 100 is in the unfolded state, a third surface 121 facing the first direction (the z-axis direction) and a fourth surface 122 facing the second direction (the -z-axis direction). In an embodiment, when the electronic device 100 is in the unfolded state, the first surface 111 of the first housing 110 and the third surface 121 of the second housing 120 may face substantially the same first direction (the z-axis direction). In an embodiment, when the electronic device 100 is in the folded state, the first surface 111 of the first housing 110 and the third surface 121 of the second housing 120 may face each other. In an embodiment, when the electronic device 100 is in the unfolded state, the second surface 112 of the first housing 110 and the fourth surface 122 of the second housing 120 may face substantially the same second direction (the -z-axis direction). In an embodiment, in the folded state of the electronic device 100, the second surface 112 of the first housing 110 and the fourth surface 122 of the second housing 120 may face away from each other. For example, when the electronic device 100 is in the folded state, the second surface 112 may face the first direction (the z-axis direction), and the fourth surface 122 may face the second direction (the -z-axis direction). In this case, the first display 400 may be invisible from the outside (in-folding type). In an embodiment, the electronic device 100 may be folded such that the second surface 112 of the first housing 110 and the fourth surface 122 of the second housing 120 face each other. In this case, the first display 400 may be disposed to be visible from the outside (out-folding type).

According to various embodiments, the first housing 110 (e.g., a first housing structure) may include a first side surface member 113 at least partially forming an exterior of an electronic device 100, and a first rear surface cover 114 coupled to the first side surface member 113 and forming at least a portion of a second surface 112 of the electronic device 100. In an embodiment, the first side surface member 113 may include a first side surface 113a, a second side surface 113b extending from one end of the first side surface 113a, and a third side surface 113c extending from the other end of the first side surface 113a. In an embodiment, the first side surface member 113 may have a rectangular (e.g., square or oblong) shape configured with the first side surface 113a, the second side surface 113b, and the third side surface 113c.

According to various embodiments, the second housing 120 (e.g., a second housing structure) may include a second side surface member 123 at least partially forming the exterior of the electronic device 100, and a second rear surface cover 124 coupled to the second side surface member 123 and forming at least a portion of a fourth surface 122 of the electronic device 100. In an embodiment, the second side surface member 123 may include a fourth side surface 123a, a fifth side surface 123b extending from one end of the fourth side surface 123a, and a sixth side surface 123c extending from the other end of the fourth side surface 123a. In an embodiment, the second side surface member 123 may be formed in a rectangular shape by the fourth side surface 123a, the fifth side surface 123b, and the sixth side surface 123c.

According to various embodiments, the first and second housings 110 and 120 are not limited to the illustrated shapes and couplings, and may be implemented by other shapes or combinations and/or couplings of components. In an embodiment, the first side surface member 113 and the first rear surface cover 114 may be integrally configured, and the second side surface member 123 and the second rear surface cover 124 may be integrally configured.

According to various embodiments, in the unfolded state of the electronic device 100, the second side surface 113b of the first side surface member 113 and the fifth side surface 123b of the second side surface member 123 may be connected to each other without a gap. In an embodiment, when the electronic device 100 is in the unfolded state, the third side surface 113c of the first side surface member 113 and the sixth side surface 123c of the second side surface member 123 may be connected to each other without a gap. According to an embodiment, the electronic device 100 may be configured such that, in the unfolded state, the sum of the lengths of the second side surface 113b and the fifth side surface 123b is greater than the length of the first side surface 113a and/or the fourth side surface 123a. In an embodiment, the electronic device 100 may be configured such that, in the unfolded state, the sum of the lengths of the third side surface 113c and the sixth side surface 123c is greater than the length of the first side surface 113a and/or the fourth side surface 123a.

Referring to FIGS. 2A and 2B, the first side member 113 and/or the second side member 123 may be made of metal or may further include polymer injected into the metal. In an embodiment, the first side surface member 113 and/or the second side surface member 123 may include at least one conductive portion 116 and/or 126 electrically split from each other through at least one split portion 1161, 1162 and/or 1261, 1262 made of polymer. In this case, the at least one conductive portion 116 and/or 126 may be used as at least a portion of an antenna operating in at least one predetermined band (e.g., a legacy band) by being electrically connected to a wireless communication circuit included in the electronic device 100.

According to various embodiments, the first rear surface cover 114 and/or the second rear surface cover 124 may be formed of, for example, at least one or a combination of at least two of coated or colored glass, ceramic, polymer, or metal (e.g., aluminum, stainless steel (STS), or magnesium).

According to various embodiments, the first display 400 may be disposed to extend from the first surface 111 of the first housing 110 across the hinge device (e.g., the hinge device 140 of FIG. 1B) to at least a portion of the third surface 121 of the second housing 120. In an embodiment, the first display 400 may include a first region 130a substantially corresponding to the first surface 111, a second region 130b corresponding to the third surface 121, and a third region 130c (e.g., a bendable region or a folding region) that connects the first region 130a and the second region 130b. In an embodiment, the third region 130c may be a portion of the first region 130a and/or the second region 130b, and may be disposed at a position corresponding to the hinge device (e.g., the hinge device 140 of FIG. 1B). In an embodiment, the electronic device 100 may include a hinge housing 141 (e.g., a hinge cover) that supports a hinge device (e.g., the hinge device 140 of FIG. 1B). In an embodiment, the hinge housing 141 may be disposed such that the hinge housing 141 is exposed to the outside when the electronic device 100 is in the folded state, and is disposed to be invisible from the outside when the electronic device 100 is in the unfolded state by being introduced into the inner space of the first housing 110 and the inner space of the second housing 120.

According to various embodiments, the electronic device 100 may include a second display 131 (e.g., a sub-display) disposed separately from the first display 400. In an embodiment, the second display 131 may be disposed to be at least partially exposed on the second surface 112 of the first housing 110. In an embodiment, when the electronic device 100 is in the folded state, the second display 131 may at least partially replace the display function of the first display 400 and displays at least part of the status information of the electronic device 100. In an embodiment, the second display 131 may be disposed to be visible from the outside through at least a portion of the first rear surface cover 114. In an embodiment, the second display 131 may be disposed on the fourth surface 122 of the second housing 120. In this case, the second display 131 may be disposed to be visible from the outside through at least a portion of the second rear surface cover 124.

According to various embodiments, the electronic device 100 may include at least one of an input device 103 (e.g., a microphone), sound output devices 101 and 102, sensor modules 104, camera devices 105 and 108, key input devices 106, or a connector port 107. In the illustrated embodiment, the input device 103 (e.g., a microphone), the sound output devices 101 and 102, the sensor modules 104, the camera device 105 and 108, the key input devices 106, or the connector port 107 is illustrated as a hole or a circle-shaped element provided in the first housing 110 or the second housing 120, but this is an illustration for explanation and is not limited thereto. According to various embodiments, the input device 103 may include at least one microphone 103 disposed in the second housing 120. In an embodiment, the input device 103 may include a plurality of microphones 103 arranged to detect the direction of sound. In an embodiment, the plurality of microphones 103 may be disposed at appropriate positions in the first housing 110 and/or the second housing 120. In an embodiment, the sound output devices 101 and 102 may include one or more speakers 101 and 102. In an embodiment, the one or more speakers 101 and 102 may include a call receiver 101 disposed in the first housing 110 and a speaker 102 disposed in the second housing 120. In an embodiment, the input device 103, the sound output devices 101 and 102, and the connector port 107 may be disposed in a space provided in the first housing 110 and/or a space provided in the second housing 120 of the electronic device 100, and may be exposed to the external environment through one or more holes provided in the first housing 110 and/or the second housing 120. In an embodiment, at least one connector port 107 may be used to transmit/receive power and/or data to/from an external electronic device. In an embodiment, the at least one connector port (e.g., an ear jack hole) may accommodate a connector (e.g., an ear jack) for transmitting/receiving an audio signal to/from an external electronic device. In an embodiment, the holes provided in the first housing 110 and/or the second housing 120 may be commonly used for the input device 103 and the sound output devices 101 and 102. In an embodiment, the sound output devices 101 and 102 may include a speaker (e.g., a piezo speaker) that is not exposed through a hole formed in the first housing 110 and/or the second housing 120.

According to various embodiments, the sensor modules 104 may generate an electrical signal or a data value corresponding to an internal operating state of the electronic device 100 or an external environmental state. In an embodiment, the sensor modules 104 may detect an external environment through the first surface 111 of the first housing 110. In an embodiment, the electronic device 100 may further include at least one sensor module arranged to detect an external environment through the second surface 112 of the first housing 110. In an embodiment, the sensor modules 104 (e.g., an illuminance sensor) may be disposed under the first display 400 to detect an external environment through the first display 400. In an embodiment, the sensor modules 104 may include at least one of a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, an illuminance sensor, a proximity sensor, a biometric sensor, an ultrasonic sensor, or an illuminance sensor 104.

According to various embodiments, the camera devices 105 and 108 may include a first camera device 105 (e.g., a front camera device) disposed on the first surface 111 of the first housing 110, and a second camera device 108 disposed on the second surface 112 of the first housing 110. In an embodiment, the electronic device 100 may further include a flash 109 disposed near the second camera device 108. In an embodiment, the camera devices 105 and 108 may include at least one lens, an image sensor, and/or an image signal processor. In an embodiment, the camera devices 105 and 108 may be arranged such that two or more lenses (e.g., a wide-angle lens, an ultra-wide-angle lens, or a telephoto lens) and two or more image sensors may be located on one surface (e.g., the first surface 111, the second surface 112, the third surface 121, or the fourth surface 122) of the electronic device 100. In an embodiment, the camera devices 105 and 108 may each include time-of-flight (TOF) lenses and/or an image sensor.

According to various embodiments, the key input devices 106 (e.g., key buttons) may be disposed on the third side surface 113c of the first side surface member 113 of the first housing 110. In an embodiment, the key input devices 106 may be disposed on at least one of the other side surfaces 113a and 113b of the first housing 110 and/or the side surfaces 123a, 123b, and 123c of the second housing 120. In an embodiment, the electronic device 100 may not include some or all of the key input devices 106, and the key input devices 106 not included in the electronic device 100 may be implemented in another form such as soft keys on the first display 400. In an embodiment, the key input devices 106 may be implemented by using pressure sensors included in the first display 400.

According to various embodiments, some of the camera devices 105 and 108 (e.g., the first camera device 105) or the sensor modules 104 may be disposed to be exposed through the first display 400. In an embodiment, the first camera device 105 or the sensor modules 104 may be optically exposed to the outside from the inner space of the electronic device 100 through an opening (e.g., a through hole) at least partially provided in the first display 400. In an embodiment, at least some of the sensor modules 104 may be arranged in the internal space of the electronic device 100 so as not to be visually exposed through the first display 400. Referring to FIG. 2B, the electronic device 100 may operate to maintain at least one predetermined folding angle in an intermediate state via a hinge device (e.g., the hinge device 140 of FIG. 1B). In this case, the electronic device 100 may control the first display 400 such that the display region corresponding to the first surface 111 and the display region corresponding to the third surface 121 display different contents, respectively. In an embodiment, the electronic device 100 may operate, via a hinge device (e.g., the hinge device 140 of FIG. 1B), in a substantially unfolded state (e.g., the unfolded state of FIG. 1A) and/or a substantially folded state (e.g., the folded state of FIG. 2A) with respect to a predetermined folding angle (e.g., an angle between the first housing 110 and the second housing 120 when the electronic device 100 is in an intermediate state). In an embodiment, when the electronic device 100 is unfolded at a predetermined folding angle via the hinge device (e.g., the hinge device 140 of FIG. 1B), and a pressing force is applied in an unfolding direction (direction A), the electronic device 100 may operate to transition to the unfolded state (e.g., the unfolded state of FIG. 1A). In an embodiment, when the electronic device 100 is unfolded at the predetermined folding angle via the hinge device (e.g., the hinge device 140 of FIG. 1B), and a pressing force is applied in a folding direction (direction B), the electronic device 100 may operate to transition to the folded state (e.g., the folded state of FIG. 2A). In an embodiment, the electronic device 100 may operate, via the hinge device (e.g., the hinge device 140 of FIG. 1B), to maintain an unfolded state (not illustrated) at various folding angles (free-stop function).

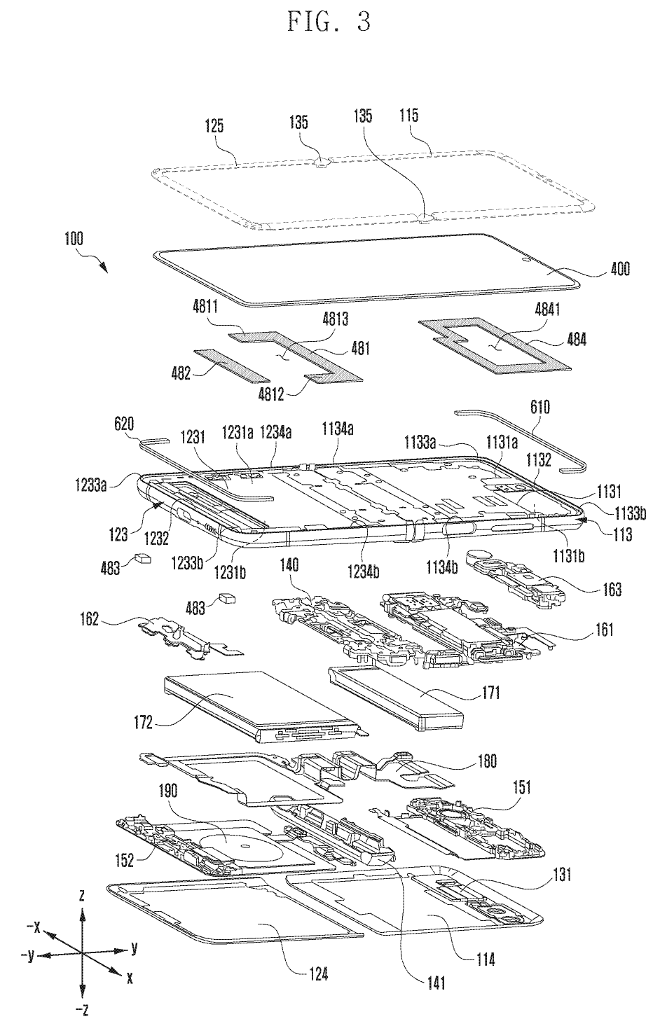

FIG. 3 is an exploded perspective view of an electronic device according to an embodiment of the disclosure.

Referring to FIG. 3, an electronic device 100 may include a first side surface member 113 (e.g., a first side surface frame), a second side surface member 123 (e.g., a second side surface frame), and a hinge device 140 (e.g., a hinge module or a hinge structure) configured to rotatably connect the first side surface member 113 and the second side surface member 123. In an embodiment, the electronic device 100 may include a first support member 1131 (e.g., a first support plate) extending at least partially from the first side surface member 113, and a second support member 1231 (e.g., a second support plate) extending at least partially from the second side surface member 123. In an embodiment, the first support member 1131 may be integrally formed with the first side surface member 113 or may be structurally coupled to the first side surface member 113. In an embodiment, the second support member 1231 may be integrally formed with or structurally coupled to the second side surface member 123. In an embodiment, a first display 400 may be disposed to be supported by the first support member 1131 and the second support member 1231.

According to various embodiments, the electronic device 100 may include one or more protective members 610 and 620 disposed to be spaced apart from the first display 400 and to surround at least a portion of the first display 400. In an embodiment, a first protective member 610 may be disposed between at least a portion of an edge of a first region (e.g., the first region 130a of FIG. 1B) of a first display 400 and an inner portion 1132 of a first housing 110. A second protective member 620 may be disposed between at least a portion of an edge of a second region (e.g., the second region 130b of FIG. 1B) of the first display 400 and an inner portion 1232 of a second housing 120. In an embodiment, the first protective member 610 may be disposed on a first inner portion 1132 of the first housing 110. The first inner portion 1132 may be a region between a first side surface 113a (e.g., the first side surface 113a of FIG. 1A) of the first side surface member 113 and a first support member 1131, and may be a region formed at least in a direction parallel to a folding axis F. In an embodiment, the second protective member 620 may be disposed on a second inner portion 1232 of the second housing 120. The second inner portion 1232 may be a region between a fourth side surface 123a (e.g., the fourth side surface 123a of FIG. 1A) of a second side surface member 123 and a second support member 1231, and may be a region formed at least in a direction parallel to the folding axis F. The first inner portion 1132 and the second inner portion 1232 may correspond to each other when the electronic device 100 is in the folded state.

In an embodiment, the first protective member 610 may be disposed to extend from one end of the first inner portion 1132 through a first bending portion 1133a to at least a portion of a third inner portion 1134a. The third inner portion 1134a may be a region between a second side surface (e.g., the second side surface 113b of FIG. 1A) of the first side surface member 113 and the first support member 1131, and may be a region extending in a direction perpendicular to the first inner portion 1132 from one end of the first inner portion 1132. The second protective member 620 may be disposed to extend from one end of the second inner portion 1232 through a second bending portion 1233a to at least a portion of a fourth inner portion 1234a. The fourth inner portion 1234a may be a region between a fifth side surface (e.g., the fifth side surface 123b of FIG. 1A) of the second side surface member 123 and the second support member 1231, and may be a region extending in a direction perpendicular to the second inner portion 1232 from one end of the second inner portion 1232.

In an embodiment, the first protective member 610 may be disposed to extend from the other end of the first inner portion 1132 through a third bending portion 1133b to at least a portion of a fifth inner portion 1134b. The fifth inner portion 1134b may be a region between a third side surface (e.g., the third side surface 113c of FIG. 1A) of the first side surface member 113 and the first support member 1131, and may be a region extending in a direction perpendicular to the first inner portion 1132 from the other end of the first inner portion 1132. In an embodiment, the second protective member 620 may be disposed to extend from the other end of the second inner portion 1232 through a fourth bending portion 1233b to at least a portion of a sixth inner portion 1234b. The sixth inner portion 1234b may be a region between a sixth side surface (e.g., the sixth side surface 123c of FIG. 1A) of the second side surface member 123 and the second support member 1231, and may be a region extending in a direction perpendicular to the second inner portion 1232 from the other end of the second inner portion 1232.

In an embodiment, one or more protective members 610 and 620 may be formed by injecting a filler constituting the one or more protective members 610 and 620 and curing the filler. However, the disclosure is not limited thereto, and the one or more protective members 610 and 620 may be integrally formed with the first housing 110 and/or the second housing 120.

In an embodiment, the electronic device 100 may include a first rear surface cover 114 coupled to the first side surface member 113 and providing a first space between the first rear surface cover 114 and the first support member 1131, and a second rear surface cover 124 coupled to the second side surface member 123 and providing a second space between the second rear surface cover 124 and the second support member 1231. In an embodiment, the first side surface member 113 and the first rear surface cover 114 may be integrally formed. In an embodiment, the second side surface member 123 and the second rear surface cover 124 may be integrally formed. In an embodiment, the first housing 110 may include the first side surface member 113, the first support member 1131, and the first rear surface cover 114. In an embodiment, the second housing 120 may include the second side surface member 123, the second support member 1231, and the second rear surface cover 124. In an embodiment, the electronic device 100 may include a second display 131 disposed to be visible from the outside through at least a portion of the first rear surface cover 114.

According to various embodiments, the electronic device 100 may include a first substrate 161 (e.g., a first substrate assembly or a main printed circuit board), a camera assembly 163, a first battery 171, or a first bracket 151 disposed in the first space between the first side surface member 113 and the first rear surface cover 114. In an embodiment, the camera assembly 163 may include a plurality of camera devices (e.g., the camera devices 105 and 108 of FIGS. 1A and 2A) and may be electrically connected to the first substrate 161. In an embodiment, the first bracket 151 may provide a support structure for supporting the first substrate 161 and/or the camera assembly 163 and improved rigidity. In an embodiment, the electronic device 100 may include a second substrate 162 (e.g., a second substrate assembly or a sub-printed circuit board), an antenna 190 (e.g., a coil member), a second battery 172, or a second bracket 152 disposed in the second space between the second side surface member 123 and the second rear surface cover 124. In an embodiment, the electronic device 100 may include a wiring member 180 (e.g., a flexible printed circuit board (FPCB)) disposed to extend from the first substrate 161 across the hinge device 140 to a plurality of electronic components (e.g., the second substrate 162, the second battery 172, or the antenna 190) disposed between the second side surface member 123 and the second rear surface cover 124, thereby providing electrical connection. In an embodiment, the antenna 190 may include a near field communication (NFC) antenna, a wireless charging antenna, and/or a magnetic secure transmission (MST) antenna.

According to various embodiments, the electronic device 100 may further include a first protective cover 115 (e.g., a first protective frame or a first decoration member) coupled along an edge of the first housing 110, and a second protective cover 125 (e.g., a second protective frame or a second decoration member) coupled along an edge of the second housing 120. In an embodiment, the first protective cover 115 and/or the second protective cover 125 may be formed of a metal or polymer material. In an embodiment, the first protective cover 115 and/or the second protective cover 125 may be used as a decoration member. In this case, the first display 400 may be disposed such that an edge of the first region 130a is invisible from the outside between the first housing 110 and the first protective cover 115. In an embodiment, the first display 400 may be disposed such that an edge of the second region 130b is invisible from the outside between the second housing 120 and the second protective cover 125. In an embodiment, the first protective cover 115 and/or the second protective cover 125 may be omitted.

According to various embodiments, the electronic device 100 may further include a protective cap 135 disposed to protect an edge of a third region (e.g., the third region 130c of FIG. 1B) of the first display 400. In this case, the first display 400 may have its edge protected by the protective cap 135 disposed at a position corresponding to the folding region (e.g., the folding region 130c of FIG. 1B). In an embodiment, the protective cap 135 may be omitted.

According to various embodiments, the first support member 1131 may include a first support surface 1131a oriented in a first direction (e.g., the z-axis direction) and a second support surface 1131b oriented in a second direction (e.g., the -z-axis direction) opposite to the first direction. In an embodiment, the second support member 1231 may include a third support surface 1231a oriented in the first direction and a fourth support surface 1231b oriented in the second direction when the electronic device 100 is in the unfolded state. In an embodiment, the first display 400 may be disposed to be supported by the first support surface 1131a of the first support member 1131 and the third support surface 1231a of the second support member 1231.

According to various embodiments, an electronic device 100 may include one or more waterproofing members 481, 482, 483, and 484 disposed between the first display 400 and the second support member 1231 and between the first display 400 and the first support member 1131. In an embodiment, among the one or more waterproofing members 481, 482, 483, and 484, some waterproofing members 481, 482, and 483 may include a first waterproofing member 481 disposed between the first display 400 and the second support member 1231, a second waterproofing member 482 connected to the first waterproofing member 481, and a third waterproofing member 483 configured to connect one end 4811 of the first waterproofing member 481 and one end of the second waterproofing member 482 and to connect the other end 4812 of the first waterproofing member 481 and the other end of the second waterproofing member 482, thereby providing a first waterproofing space 4813. In an embodiment, the first waterproofing member 481, the second waterproofing member 482, and/or the third waterproofing member 483 may be formed integrally. In an embodiment, among the one or more waterproofing members 481, 482, 483, and 484, a waterproofing member 484 may include a fourth waterproofing member 484 disposed between the first display 400 and the first support member 1131 and provided with a closed-loop-shaped second waterproofing space 4841. In an embodiment, a plurality of electronic elements including a control circuit (e.g., a display driver IC (DDI)) of a first display 400 may be disposed in the sealed first waterproofing space 4813 formed by the first waterproofing member 481, the second waterproofing member 482, and the third waterproofing member 483 between the first display 400 and the second support member 1231, thereby being protected from external moisture and/or foreign substances. In an embodiment, at least one electronic component (e.g., a sensor module (e.g., the sensor module 104 of FIG. 1A) and/or a camera device (e.g., the camera device 105 of FIG. 1A)) disposed through the first support member 1131 may be disposed in the second waterproofing space 4841 formed by the closed-loop shape of the fourth waterproofing member 484 between the first display 400 and the first support member 1131, thereby being protected from external moisture and/or foreign substances. In an embodiment,

there is no limitation on types of components disposed in the first waterproofing space 4813 and/or the second waterproofing space 4841.

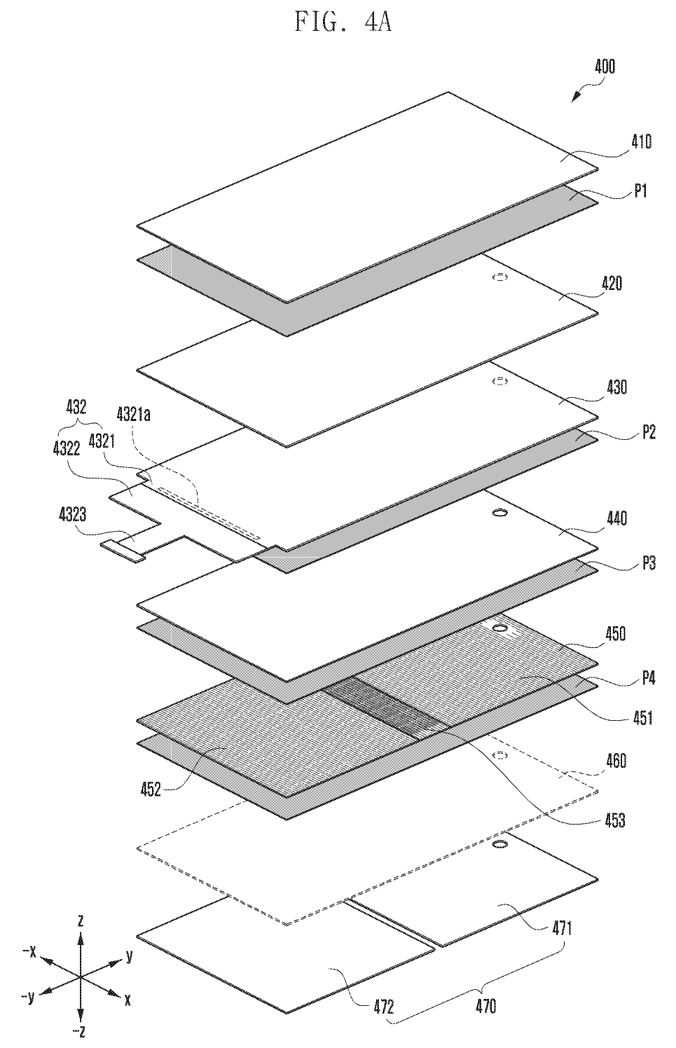

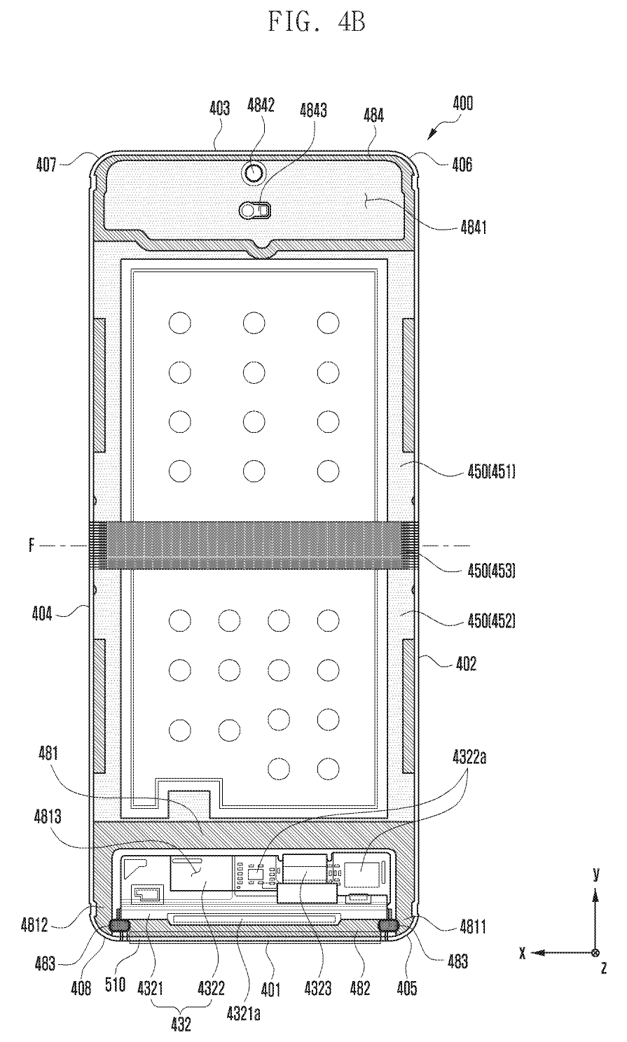

FIG. 4A is an exploded perspective view of a flexible display according to an embodiment of the disclosure.

FIG. 4B is a view illustrating a configuration of a flexible display as viewed from a rear side according to an embodiment of the disclosure.

The flexible display 400 of FIGS. 4A and 4B may be at least partially similar to the first display 400 of FIG. 1A, or may further include other embodiments of a flexible display.

A display (e.g., the flexible display 400) according to embodiments of the disclosure may include an unbreakable (UB)-type organic light-emitting diode (OLED) display (e.g., a curved display). However, the disclosure is not limited thereto, and the flexible display 400 may include an on-cell-touch active-matrix organic light-emitting diode (AMOLED) (OCTA)-type flat display.

Referring to FIGS. 4A and 4B, the flexible display 400 may include a window layer 410, a polarizer (POL) 420 (e.g., a polarizing film), a display panel 430, a polymer layer 440, a support plate 450, and a reinforcement plate 470 which are sequentially disposed on the rear surface of the window layer 410 (e.g., in the -z-axis direction). In some embodiments, the flexible display 400 may include a digitizer 460 disposed between the support plate 450 and the reinforcement plate 470. In some embodiments, the digitizer 460 may be disposed between the polymer layer 440 and the support plate 450. For example, when the flexible display 400 is a POL-less display, the polarizer may be omitted, and a transparent reinforcement layer (e.g., a buffer layer) may be further disposed at that position. In some embodiments, the reinforcement plate 470 may be omitted.

According to various embodiments, the window layer 410 may include a first layer and a second layer sequentially laminated. In an embodiment, the first layer may be formed of a polymer (e.g., polyethylene terephthalate (PET), polyimide (PI), or thermoplastic polyurethane (TPU)). In an embodiment, the second layer may be formed of glass. According to an embodiment, the second layer may include ultra-thin glass (UTG). In some embodiments, the flexible display 400 may further include a coating layer formed as a part of the window layer 410 and disposed on the first layer. In such cases, the coating layer may include a hard coating (HC) layer, an anti-reflection/low-reflection (AR/LR) coating layer, a shatter-proof (SP) coating layer, or an anti-fingerprint (AF) coating layer. In some embodiments, the coating layer may be formed on at least one of a region between the first layer and the second layer, a side surface of the first layer, or a rear surface or a side surface of the second layer.

According to various embodiments, the window layer 410, the polarizer 420, the display panel 430, the polymer layer 440, and the support plate 450 may be disposed to cross at least a portion of the first surface (e.g., the first surface 111 of FIG. 1A) of the first housing (e.g., the first housing 110 of FIG. 1A) and the third surface (e.g., the third surface 121 of FIG. 1A) of the second housing (e.g., the second housing 120 of FIG. 1A). In an embodiment, the reinforcement plate 470 may include a first reinforcement plate 471 corresponding to the first housing (e.g., the first housing 110 of FIG. 1A) and a second reinforcement plate 472 corresponding to the second housing (e.g., the second housing 120 of FIG. 1A). In an embodiment, the reinforcement plate 470 may provide rigidity for the flexible display 400 and may be used as a ground to prevent malfunction of the flexible display 400. In an embodiment, the reinforcement plate 470 may be formed of a metal material. In an embodiment, the reinforcement plate 470 may be formed of SUS or Al. In an embodiment, the window layer 410, the polarizer 420, the display panel 430, the polymer layer 440, the support plate 450, and the reinforcement plates 471 and 472 may be attached to each other via adhesive members P1, P2, P3, and P4 (or an adhesive). For example, the adhesive members P1, P2, P3, and P4 may include at least one of an optical clear adhesive (OCA), a pressure-sensitive adhesive (PSA), a thermally reactive adhesive, a general adhesive, or a double-sided tape.

According to various embodiments, the display panel 430 may include a plurality of pixels and a wiring structure (e.g., an electrode pattern). In an embodiment, the polarizer 420 may selectively allow light generated from a light source of the display panel 430 and vibrating in a predetermined direction to pass therethrough. In an embodiment, the display panel 430 and the polarizer 420 may be integrally formed. In an embodiment, the flexible display 400 may include a touch panel (not illustrated).

According to various embodiments, the polymer layer 440 may be disposed under the display panel 430 to provide a dark background for ensuring visibility of the display panel 430, and may be made of a buffering material for a buffering action. In some embodiments, in order to ensure waterproofing of the flexible display 400, the polymer layer 440 may be removed or disposed under the support plate 450. In some embodiments, the polymer layer 440 may be omitted when the support plate 450 is made of an opaque material.

According to various embodiments, the support plate 450 may provide a bendable property to the flexible display 400. For example, the support plate 450 may be made of a non-metallic sheet material, such as fiber-reinforced plastics (FRP) (e.g., carbon fiber-reinforced plastics (CFRP) or glass fiber-reinforced plastics (GFRP)), having a rigid property to support the display panel 430. In an embodiment, the support plate 450 may include a first flat portion 451 corresponding to the first housing (e.g., the first housing 110 of FIG. 1A), a second flat portion 452 corresponding to the second housing (e.g., the second housing 120 of FIG. 1A), and a flexible portion 453 (or a bending portion) connecting the first flat portion 451 and the second flat portion 452. In an embodiment, the flexible portion 453 may include a plurality of openings formed to penetrate from the top surface to the rear surface of the support plate 450 and/or a plurality of recesses formed in a portion of the top surface and/or a portion of the rear surface in order to improve the bendability. In an embodiment, the bending property of the flexible portion 453 may be determined through at least one of the size, shape, or arrangement density of at least some of the plurality of openings and/or at least some of the plurality of recesses. In some embodiments, the support plate 450 may be made of a metal material such as steel use stainless (SUS) (e.g., stainless steel (STS)), Cu, Al, or a metal CLAD (e.g., a laminated member in which SUS and Al are alternately disposed). In this case, throughout the entire area of the support plate 450, the multiple openings may be formed to induce the detection operation of the digitizer 460 disposed under the support plate. In an embodiment, the support plate 450 may help reinforce the rigidity of the electronic device (e.g., the electronic device 100 of FIG. 1A), may shield surrounding noise, and may also be used to dissipate heat emitted from surrounding heat dissipating components.

According to various embodiments, the display 400 may include a digitizer 460 disposed under the support plate 450 and configured as a detection member configured to receive an input of an electronic pen (e.g., a stylus). In an embodiment, the digitizer 460 may include coil members disposed on a dielectric substrate (e.g., a dielectric film or a dielectric sheet) to detect an electromagnetically induced resonance frequency applied from an electronic pen. In some embodiments, the digitizer 460 may include a first digitizer disposed in a region corresponding to a first housing (e.g., the first housing 110 of FIG. 1A), and a second digitizer electrically connected to the first digitizer and disposed in a region corresponding to a second housing (e.g., the second housing 120 of FIG. 1A).

According to various embodiments, the flexible display 400 may further include one or more functional members (not illustrated) disposed between the polymer layer 440 and the support plate 450 or under the support plate 450. In an embodiment, the functional members may include a graphite sheet for heat dissipation, a post-touch FPCB, a fingerprint sensor FPCB, an antenna radiator for communication, or a conductive/non-conductive tape. In an embodiment, when the functional members are not bendable, the functional members may be disposed separately in the first housing (e.g., the first housing 110 of FIG. 1A) and the second housing (e.g., the second housing 120 of FIG. 1A). In an embodiment, when the functional members are bendable, the functional members may be disposed from the first housing (e.g., the first housing 110 of FIG. 1A) to at least a portion of the second housing (e.g., the second housing 120 of FIG. 1A) via a hinge device (e.g., the hinge device 140 of FIG. 3).

According to various embodiments, the flexible display 400 may be formed in a rectangular shape. In an embodiment, the flexible display 400 may include a first edge 403, a second edge 401 parallel to the first edge 403, a third edge 402 connecting one end of the first edge 403 and one end of the second edge 401 in a direction perpendicular thereto, and a fourth edge 404 connecting the other end of the first edge 403 and the other end of the second edge 401 in a direction perpendicular thereto.

In an embodiment, the flexible display 400 may include a first curved edge 405 configured to connect the second edge 401 and the third edge 402 and formed in a rounded shape, a second curved edge 406 configured to connect the third edge 402 and the first edge 403 and formed in a rounded shape, a third curved edge 407 configured to connect the first edge 403 and the fourth edge 404 and formed in a rounded shape, and a fourth curved edge 408 configured to connect the fourth edge 404 and the second edge 401 and formed in a rounded shape.

In an embodiment, the second edge 401 may be disposed at a position corresponding to a fourth side surface (e.g., the fourth side surface 123a of FIG. 1A) of the second housing (e.g., the second housing 120 of FIG. 1A). In an embodiment, the third edge 402 may be disposed at a position corresponding to a second side surface (e.g., the second side surface 113b of FIG. 1A) of the first housing (e.g., the first housing 110 of FIG. 1A) and a fifth side surface (e.g., the fifth side surface 123b of FIG. 1A) of the second housing (e.g., the second housing 120 of FIG. 1A). In an embodiment, the first edge 403 may be disposed at a position corresponding to a first side surface (e.g., the first side surface 113a of FIG. 1A) of the first housing (e.g., the first housing 110 of FIG. 1A). According to an embodiment, the fourth edge 404 may be disposed at a position corresponding to a third side surface (e.g., the third side surface 113c of FIG. 1A) of the first housing (e.g., the first housing 110 of FIG. 1A) and a sixth side surface (e.g., the sixth side surface 123c of FIG. 1A) of the second housing (e.g., the second housing 120 of FIG. 1A).

According to various embodiments, the flexible display 400 may include a bending portion 432 disposed such that, from the second edge 401, at least a portion of the flexible display 400 is bent from the display panel 430 toward a rear surface (e.g., in the -z-axis direction) of the flexible display 400. In an embodiment, the bending portion 432 may include an extension portion 4321 extending from the display panel 430 and including a control circuit 4321a, and a flexible substrate 4322 electrically connected to the extension portion 4321 and including a plurality of electronic elements. In an embodiment, the control circuit 4321a may include a display driver IC (DDI) or a touch display driver IC (TDDI) mounted on the extension portion 4321 having an electrical wiring structure. In an embodiment, the bending portion 432 may include a chip-on-panel or chip-on-plastic (COP) structure in which the control circuit 4321a is directly disposed on the extension portion 4321. In some embodiments, the bending portion 432 may include a chip-on-film (COF) structure in which the control circuit 4321a is mounted on a separate connection film (not illustrated) that connects the extension portion 4321 and the flexible substrate 4322. In an embodiment, the flexible display 400 may include a plurality of electronic elements (e.g., the electronic elements 4322a of FIG. 4B) disposed on the flexible substrate 4322. In an embodiment, the flexible display 400 may include an FPCB connection portion 4323 (e.g., a connector portion) extending from the flexible substrate 4322 and electrically connected to a substrate (e.g., the second substrate 162 of FIG. 3) of an electronic device (e.g., the electronic device 100 of FIG. 3). In an embodiment, the plurality of electronic elements may include a touch IC, a display flash memory, an ESD prevention diode, a pressure sensor, a fingerprint sensor, or a passive element such as a decap. In another embodiment, when the bending portion 432 is disposed in a region of the flexible display 400 facing the first housing (e.g., the first housing 110 of FIG. 1A), the FPCB connection portion 4323 may be electrically connected to another substrate (e.g., the first substrate 161 of FIG. 3) of the electronic device (e.g., the electronic device 100 of FIG. 3).

According to various embodiments, an electronic device (e.g., the electronic device 100 of FIG. 3) may include one or more waterproofing members 481, 482, 483, and 484. In an embodiment, the one or more waterproofing members 481, 482, and 483 may include first, second, and third waterproofing members 481, 482, and 483 disposed to correspond to at least a portion of the second housing (e.g., the second housing 120 of FIG. 1A), and arranged to form a first waterproofing space 4813 for protecting a control circuit 4321a disposed on the extension portion 4321 of the bending portion 432 and a plurality of electronic elements 4322a disposed on the flexible substrate 4322 from external moisture and/or foreign substances. In an embodiment, the one or more waterproofing members may include a fourth waterproofing member 484 disposed to correspond to at least a portion of the second housing. In an embodiment, the fourth waterproofing member 484 may provide a sealed second waterproofing space 4841. In an embodiment, the electronic device (e.g., the electronic device 100 of FIG. 1A) may include one or more electronic components disposed in a first arrangement region 4842 and a second arrangement region 4843 provided in at least a portion of the second waterproofing space 4841. In an embodiment, the one or more electronic components may include a camera device (e.g., the camera device 105 of FIG. 1A) disposed in the first arrangement region 4842 and a sensor module (e.g., the sensor module 104 of FIG. 1A) disposed in the second arrangement region 4843.

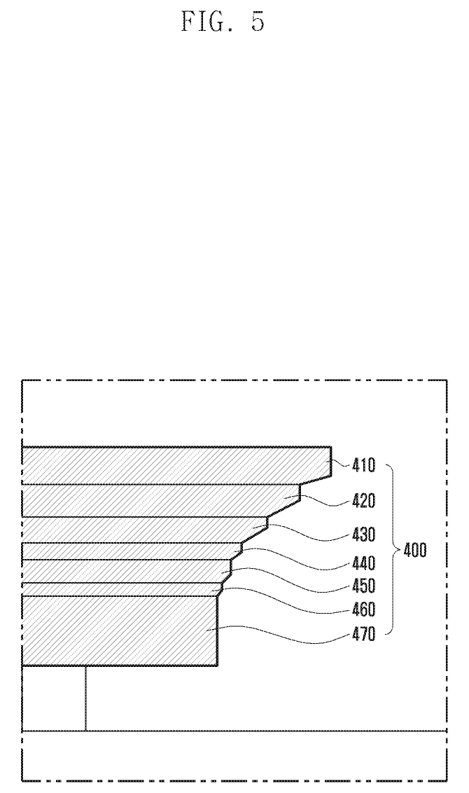

FIG. 5 is a cross-sectional view schematically illustrating an interlayer slip phenomenon occurring when a flexible display is folded according to an embodiment of the disclosure.

Referring to FIG. 5, when the electronic device 100 is in the folded state, an interlayer slip phenomenon may occur in which adjacent layers of a plurality of layers 410, 420, 430, 440, 450, 460, and 470 constituting the flexible display 400 relatively slide with respect to each other. In an embodiment, in consideration of such an interlayer slip phenomenon, the electronic device 100 may be configured to form a space (e.g., the first inner portion 1132 of FIG. 3) between a first edge (e.g., the first edge 403 of FIG. 4B) of the flexible display 400 and a first side surface member (e.g., the first side surface member 113 of FIG. 3) and/or a space (e.g., the second inner portion 1232 of FIG. 3) between a second edge (e.g., the second edge 401 of FIG. 4B) of the flexible display 400 and a second side surface member (e.g., the second side surface member 123 of FIG. 3).

When the electronic device 100 is folded, among the plurality of layers constituting the flexible display 400, a layer stacked closer to a side in a first direction (e.g., the z-axis direction) with respect to the unfolded state of the electronic device 100 may have a larger displacement due to interlayer slip. That is, when the electronic device 100 is folded, among the plurality of layers constituting the flexible display 400, a layer stacked closer to the side in the first direction (e.g., the z-axis direction) with respect to the unfolded state of the electronic device 100 may be more reduced in a vertical distance between the first edge (e.g., the first edge 403 of FIG. 4B) of the flexible display 400 and the first side surface member (e.g., the first side surface member 113 of FIG. 3) and/or a vertical distance between the second edge (e.g., the second edge 401 of FIG. 4B) of the flexible display 400 and the second side surface member (e.g., the second side surface member 123 of FIG. 3). If the vertical distance between the first edge (e.g., the first edge 403 of FIG. 4B) of the flexible display 400 and the first side surface member (e.g., the first side surface member 113 of FIG. 3) and/or the vertical distance between the second edge (e.g., the second edge 401 of FIG. 4B) of the flexible display 400 and the second side surface member (e.g., the second side surface member 123 of FIG. 3) is excessively reduced without considering the interlayer slip phenomenon, there may be a problem in that surface quality of the flexible display 400 is degraded. Conversely, if the vertical distance is excessively increased, there may be a problem in that a user may feel discomfort when using the electronic device 100.

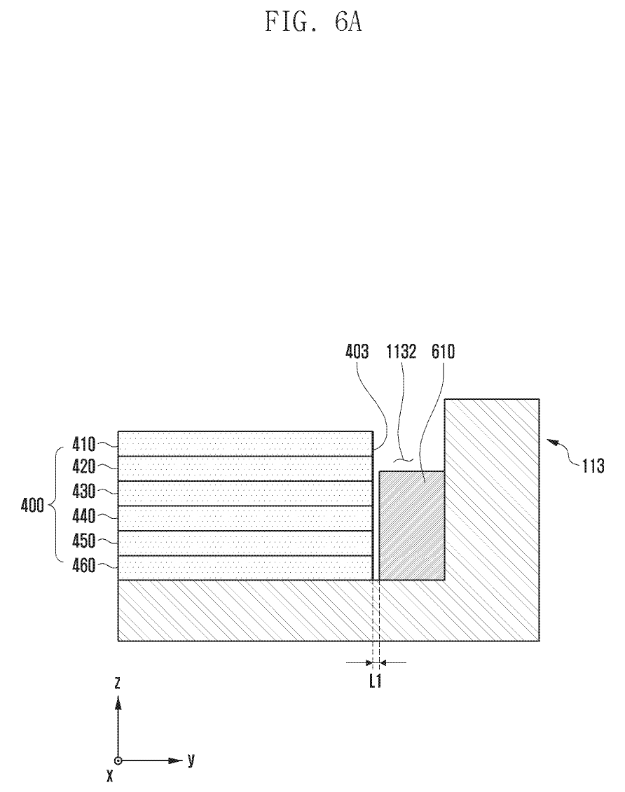

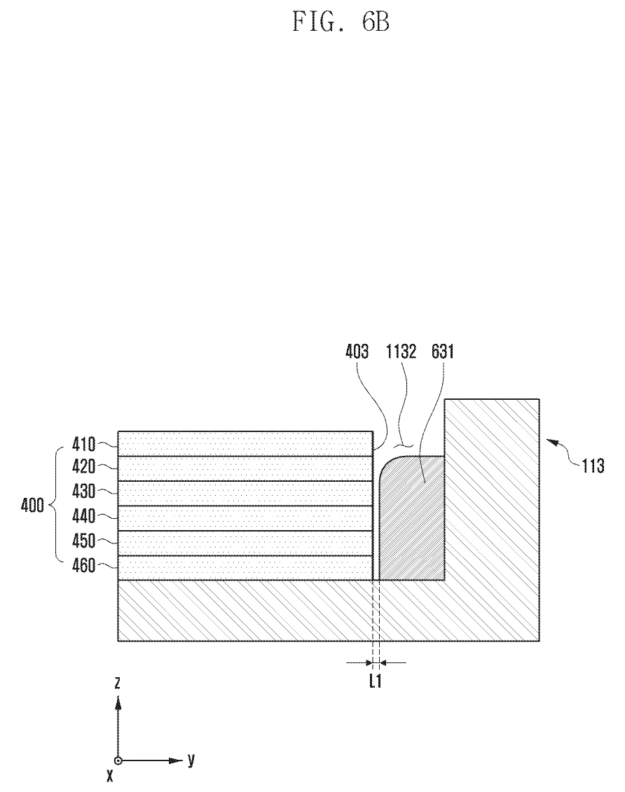

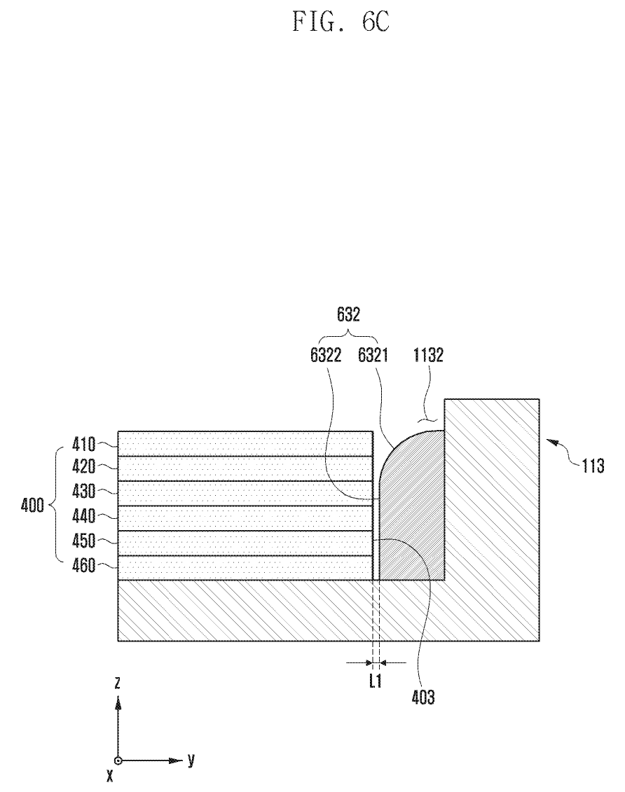

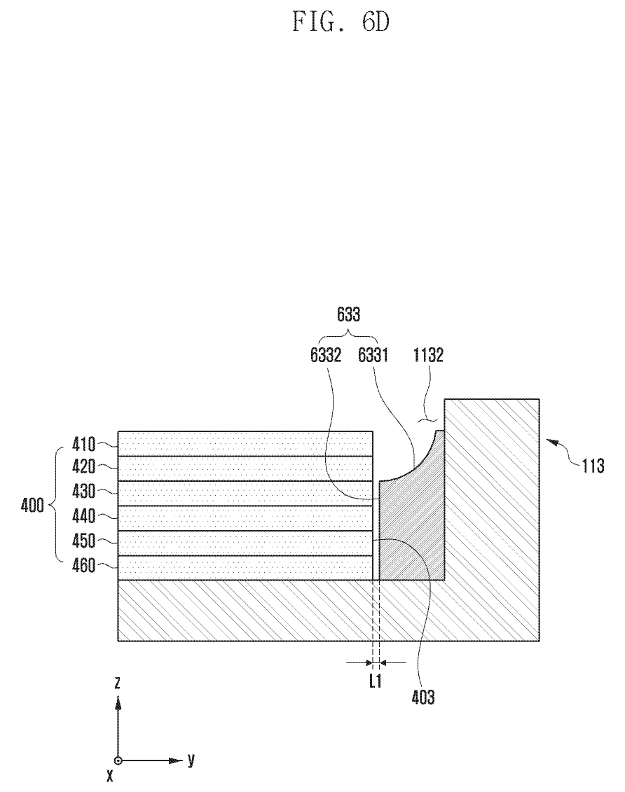

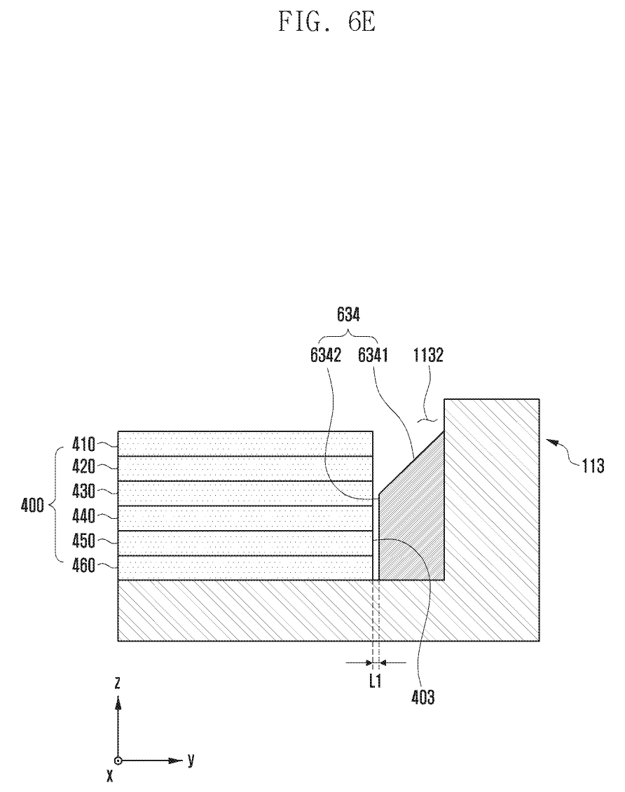

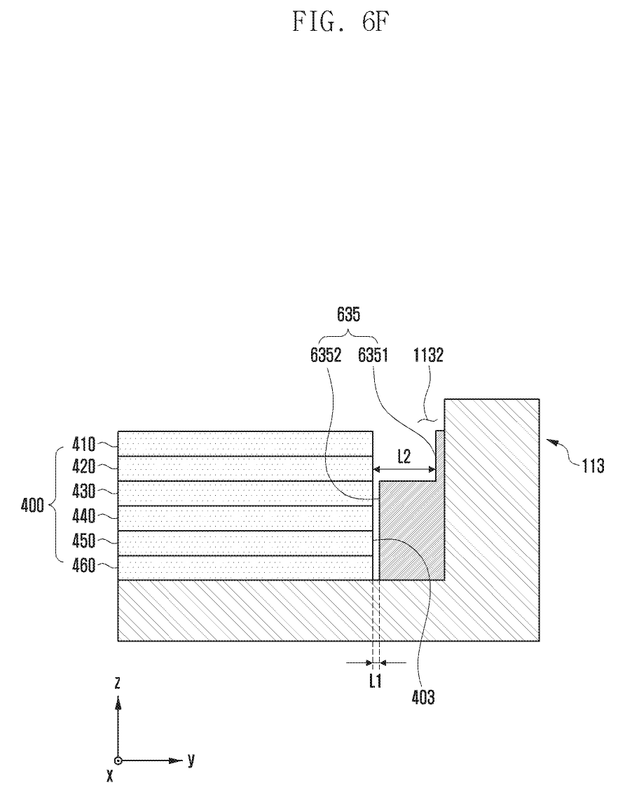

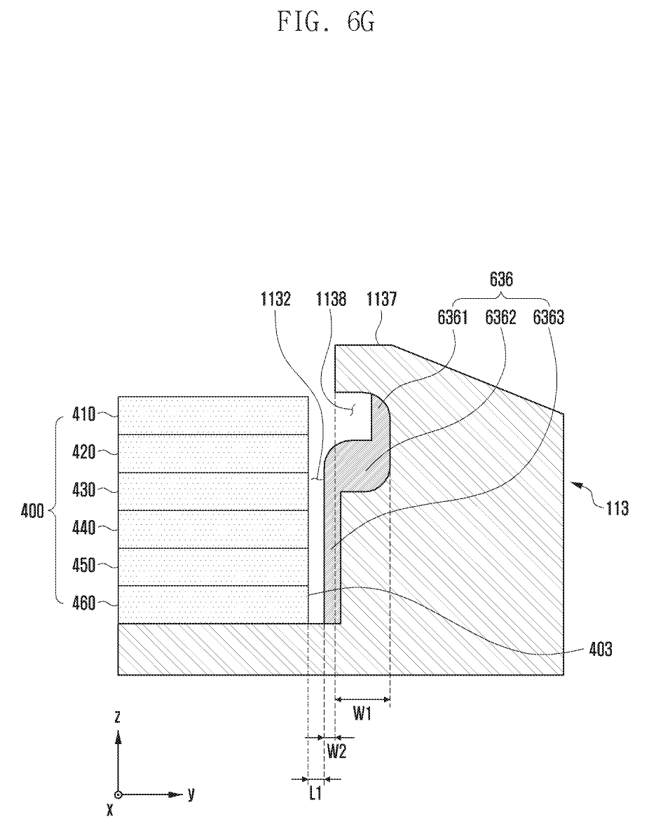

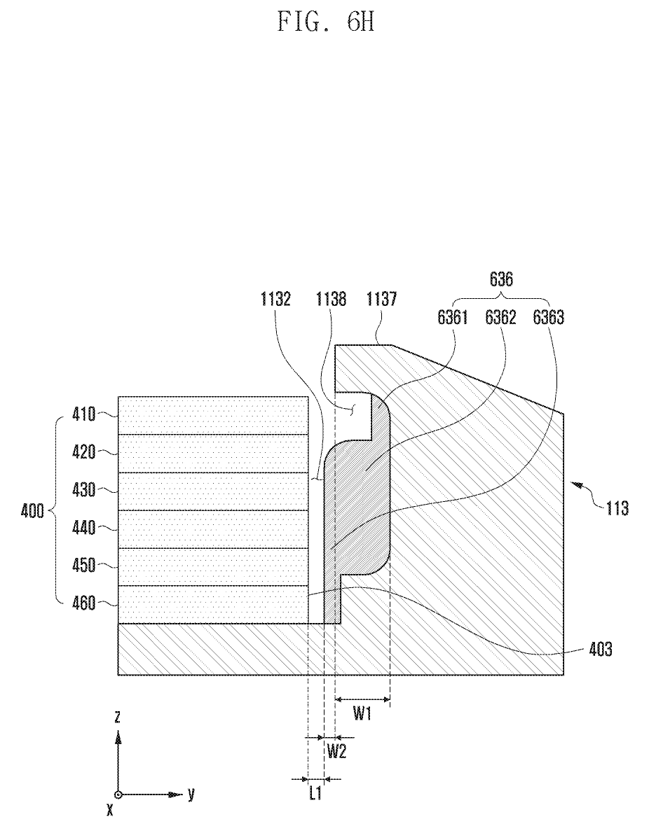

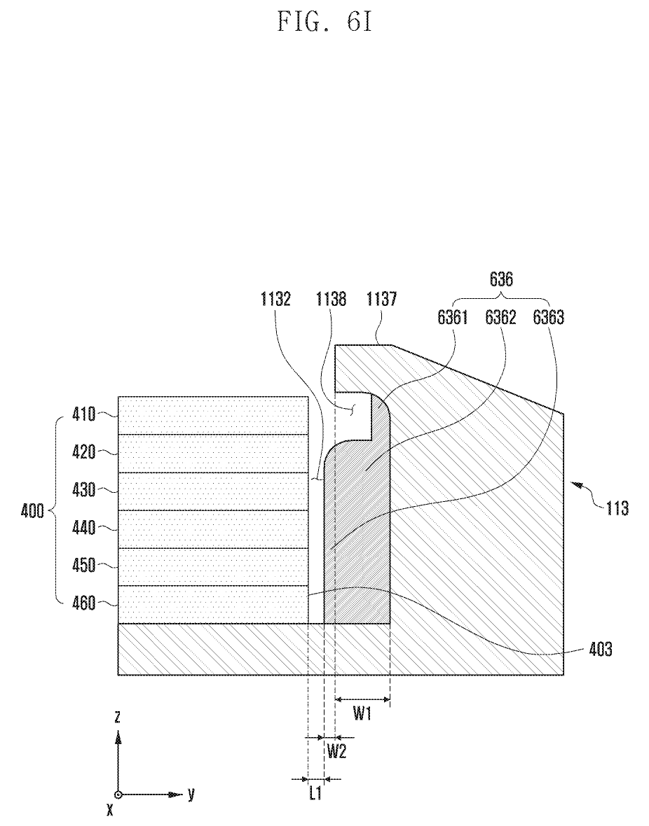

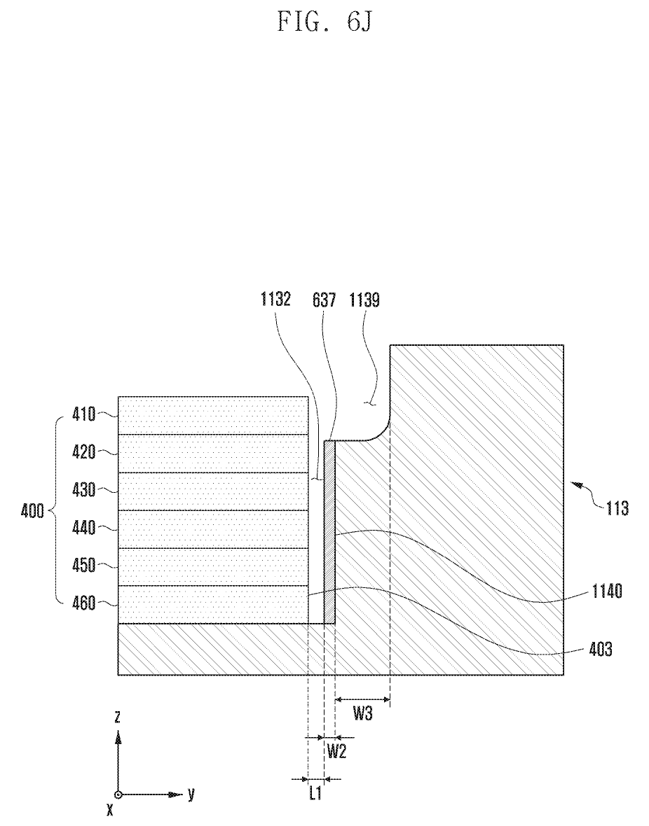

FIGS. 6A, 6B, 6C, 6D, 6E, 6F, 6G, 6H, 6I, and 6J are views illustrating protective members, as viewed along line 6-6 of FIG. 1A according to various embodiments of the disclosure.

According to various embodiments, an electronic device 100 may include one or more protective members (e.g., the first protective member 610 and/or the second protective member 620 of FIG. 3).

Referring to FIGS. 6A to 6J, although the figures illustrate only a first protective member 610 (e.g., the first protective member 610 of FIG. 3) according to various embodiments, shapes of the first protective members 610, 631, 632, 633, 634, 635, 636, and 637 according to the various embodiments of FIGS. 6A - 6J may be symmetrically and identically applied to a second protective member (e.g., the second protective member 620 of FIG. 3).

According to various embodiments, the first protective member (e.g., the first protective member 610 of FIG. 3) may be disposed in a first inner portion (e.g., the first inner portion 1132 of FIG. 3). The first protective member (e.g., the first protective member 610 of FIG. 3) may be disposed to face a first edge (e.g., the first edge 403 of FIG. 4B) of the flexible display 400. The second protective member (e.g., the second protective member 620 of FIG. 3) may be disposed in a second inner portion (e.g., the second inner portion 1232 of FIG. 3). The second protective member (e.g., the second protective member 620 of FIG. 3) may be disposed to face a second edge (e.g., the second edge 401 of FIG. 4B) of the flexible display 400.

In an embodiment, a first protective member (e.g., the first protective member 610 of FIG. 3) may be disposed to extend from one end of a first inner portion (e.g., the first inner portion 1132 of FIG. 3) to at least a portion of a third inner portion 1134a via a first bending portion 1133a. The first protective member (e.g., the first protective member 610 of FIG. 3) may be disposed to face a second curved edge 406 and at least a portion of a third edge 402 of the flexible display 400. A second protective member (e.g., the second protective member 620 of FIG. 3) may be disposed to extend from one end of a second inner portion 1232 to at least a portion of a fourth inner portion 1234a via a second bending portion 1233a. The second protective member (e.g., the second protective member 620 of FIG. 3) may be disposed to face a first curved edge 405 and at least another portion of the third edge 402 of the flexible display 400.

In an embodiment, the first protective member 610 may be disposed to extend from the other end of the first inner portion 1132 through a third bending portion 1133b to at least a portion of a fifth inner portion 1134b. The first protective member 610 may be disposed to face a third curved edge 407 and at least a portion of a fourth edge 404 of the flexible display 400.

The second protective member (e.g., the second protective member 620 of FIG. 3) may be disposed to extend from the other end of the second inner portion 1232 to at least a portion of a sixth inner portion 1234b via a fourth bending portion 1233b. The second protective member (e.g., the second protective member 620 of FIG. 3) may be disposed to face a fourth curved edge 408 and at least another portion of the fourth edge 404 of the flexible display 400.

In an embodiment, the first protective member (e.g., the first protective member 610 of FIG. 3) may be disposed to be spaced apart by a predetermined distance L1 from the first edge (e.g., the first edge 403 of FIG. 4B) of the flexible display 400 facing the first inner portion (e.g., the first inner portion 1132 of FIG. 3), and the second protective member (e.g., the second protective member 620 of FIG. 3) may be disposed to be spaced apart by the predetermined distance L1 from the second edge (e.g., the second edge 401 of FIG. 4B) of the flexible display 400 facing the second inner portion (e.g., the second inner portion 1232 of FIG. 3). In an embodiment, a state in which the flexible display 400 is in an unfolded state may be defined as a first state, and a state in which the flexible display 400 is in a folded state may be defined as a second state. In the first state, the first protective member 610 and the first edge 403 of the flexible display 400 may be spaced apart from each other by the predetermined distance L1. The second protective member 620 and the second edge 401 of the flexible display 400 may be spaced apart from each other by the predetermined distance L1. Preferably, the predetermined distance L1 may be about 0.05 mm to 0.15 mm. However, the predetermined distance L1 is not limited thereto and may be changed in consideration of a use environment such as a temperature at which the electronic device 100 is used, or an interlayer slip displacement of a plurality of layers 410, 420, 430, 440, 450, 460, and 470 constituting the flexible display 400.

In the second state, at least a portion of the first protective member 610 and the first edge 403 of the flexible display 400 may be spaced apart from each other by a distance smaller than the predetermined distance L1 or may be configured to be substantially in contact with each other. At least a portion of the second protective member 620 and the second edge 401 of the flexible display 400 may be spaced apart from each other by a distance smaller than the predetermined distance L1 or may be configured to be substantially in contact with each other. Here, being substantially in contact may mean a state in which the protective member 610 or 620 is in contact with the flexible display 400 without an external impact being applied to the flexible display 400. At least a portion of the first edge 403 and at least a portion of the second edge 401 of the flexible display 400 may refer to a layer that protrudes most in the second state (e.g., the window layer 410 of FIG. 5) among the plurality of layers constituting the flexible display.

According to various embodiments, the electronic device 100 may be configured such that the first protective member (e.g., the first protective member 610 of FIG. 3) is disposed to be spaced apart by the predetermined distance L1 from the first edge (e.g., the first edge 403 of FIG. 4B) of the flexible display 400 facing the first inner portion (e.g., the first inner portion 1132 of FIG. 3), and the second protective member (e.g., the second protective member 620 of FIG. 3) is disposed to be spaced apart by the predetermined distance L1 from the second edge (e.g., the second edge 401 of FIG. 4B) of the flexible display 400 facing the second inner portion (e.g., the second inner portion 1232 of FIG. 3), thereby lowering a level of difficulty in maintenance operations such as repair and replacement of components of the electronic device 100.

In an embodiment, one or more protective members (e.g., the first protective member 610 and/or the second protective member 620 of FIG. 3) may be formed to have a height lower than or substantially equal to that of the flexible display 400. According to various embodiments, by including the one or more protective members 610 and 620, the electronic device 100 may protect the flexible display 400 from an external impact. In addition, the electronic device 100 may be configured to prevent interference with an interlayer slip phenomenon of the plurality of layers 410, 420, 430, 440, 450, 460, and 470 constituting the flexible display 400, thereby maintaining improved surface quality. This may prevent a user from feeling discomfort in the display when using the electronic device 100.

Referring to FIG. 6A, in an embodiment, the electronic device 100 may include a protective member 610 (e.g., the first protective member 610 and/or the second protective member 620 of FIG. 3) configured such that a perpendicular distance from a first edge (e.g., the first edge 403 of FIG. 4B), which is a side surface of the flexible display 400, to the protective member 610 is uniformly formed as a predetermined distance L1. In an embodiment, the protective member 610 may have a rectangular cross-sectional shape when viewed in a direction parallel to a folding axis (e.g., F of FIG. 1A) of the flexible display 400 (e.g., the X-axis direction). In an embodiment, the protective member 610 may be formed to have a height lower than that of the flexible display 400. The height of the protective member 610 is not necessarily limited to that illustrated in FIG. 6A and may be formed so as not to correspond to layers having relatively large interlayer slip displacement among the plurality of layers 410, 420, 430, 440, 450, and 460 constituting the flexible display 400.

Referring to FIG. 6B, in an embodiment, the electronic device 100 may include a protective member 631 (e.g., the first protective member 610 and/or the second protective member 620 of FIG. 3) having an upper edge (e.g., in the z-axis direction) formed in a rounded shape adjacent to a first edge (e.g., the first edge 403 of FIG. 4B) which is a side surface of the flexible display 400. In an embodiment, by forming an upper edge (e.g., in the z-axis direction) of the protective member 631 in a rounded shape in a direction facing the flexible display 400 (e.g., in the -y-axis direction), it may be possible to secure a space for interlayer slip displacement of a polarizer 420, which has a relatively larger interlayer slip displacement than layers stacked under the polarizer 420.

Referring to FIGS. 6C - 6E, according to various embodiments, the electronic device 100 may include a protective member 632, 633, or 634 (e.g., the first protective member 610 and/or the second protective member 620 of FIG. 3) including a first protective surface (e.g., the first protective surface 6321 of FIG. 6C, the first protective surface 6331 of FIG. 6D, or the first protective surface 6341 of FIG. 6E) and a second protective surface (e.g., the second protective surface 6322 of FIG. 6C, the second protective surface 6332 of FIG. 6D, or the second protective surface 6342 of FIG. 6E). The first protective surface (e.g., the first protective surface 6321 of FIG. 6C, the first protective surface 6331 of FIG. 6D, or the first protective surface 6341 of FIG. 6E) may be formed to be inclined in a direction toward a side surface of the flexible display 400, that is, the first edge (e.g., the first edge 403 of FIG. 4B). The second protective surface (e.g., the second protective surface 6322 of FIG. 6C, the second protective surface 6332 of FIG. 6D, or the second protective surface 6342 of FIG. 6E) may be a surface extending from the first protective surface (e.g., the first protective surface 6321 of FIG. 6C, the first protective surface 6331 of FIG. 6D, or the first protective surface 6341 of FIG. 6E) and having a uniform perpendicular distance from the first edge (e.g., the first edge 403 of FIG. 4B) which is a side surface of the flexible display 400. According to various embodiments, by forming the first protective surface (e.g., the first protective surface 6321 of FIG. 6C, the first protective surface 6331 of FIG. 6D, or the first protective surface 6341 of FIG. 6E) in an inclined shape in a direction toward the first edge (e.g., the first edge 403 of FIG. 4B), which is a side surface of the flexible display 400, a space for displacement caused by interlayer slip of the window layer 410 and the polarizer 420, which have relatively large interlayer slip displacement, may be secured, and a protective member having a height substantially equal to that of the flexible display 400 may be formed. Accordingly, the plurality of layers 410, 420, 430, 440, 450, and 460 constituting the flexible display 400 may be protected from an external impact without interference caused by an interlayer slip phenomenon. In addition, the electronic device 100 may be configured such that, when the electronic device 100 is in the unfolded state, a gap between the first edge (e.g., the first edge 403 of FIG. 4B) of the flexible display 400 and a first side surface member (e.g., the first side surface member 113 of FIG. 1A) appears to be reduced when viewed from the outside.

Referring to FIG. 6C, in an embodiment, the electronic device 100 may include a protective member 632 (e.g., the first protective member 610 and/or the second protective member 620 of FIG. 3) in which a first protective surface 6321 is formed as a curved surface protruding outward. In an embodiment, by forming the first protective surface 6321 as a curved surface protruding outward, interference caused by interlayer slip movement of the window layer 410 of the flexible display 400 may be minimized.

Referring to FIG. 6D, in an embodiment, the electronic device 100 may include a protective member 633 (e.g., the first protective member 610 and/or the second protective member 620 of FIG. 3) in which a first protective surface 6331 is formed as a curved surface recessed inward. In an embodiment, by forming the first protective surface 6331 as a curved surface recessed inward, the electronic device 100 may be configured to minimize interference caused by interlayer slip movement not only of the window layer 410 but also of the polarizer 420 of the flexible display 400.

Referring to FIG. 6E, in an embodiment, the electronic device 100 may include a protective member 633 (e.g., the first protective member 610 and/or the second protective member 620 of FIG. 3) in which a first protective surface 6341 is formed as a flat surface. In an embodiment, by forming the first protective surface 6331 as a flat surface, it may be advantageous in terms of manufacturing a dummy member 700 for forming the protective member 633.

Referring to FIG. 6F, in an embodiment, the electronic device 100 may include a protective member 635 (e.g., the first protective member 610 and/or the second protective member 620 of FIG. 3) including a first protective surface 6351 formed to be spaced apart from a first edge (e.g., the first edge 403 of FIG. 4B), which is a side surface of the flexible display 400, by a distance L2 greater than a predetermined distance L1, and a second protective surface 6352 formed to be stepped from the first protective surface 6351 and spaced apart from the first edge (e.g., the first edge 403 of FIG. 4B) of the flexible display 400 by the predetermined distance L1. In an embodiment, by forming the first protective surface 6351 and the second protective surface 6352 of the protective member 635 in a stepped shape, it may be possible to secure a space that allows movement of the window layer 410 and the polarizer 420, which have relatively large interlayer slip displacement, and to configure the electronic device 100 such that, when the electronic device 100 is in the unfolded state, a gap between the first edge (e.g., the first edge 403 of FIG. 4B) of the flexible display 400 and a first side surface member (e.g., the first side surface member 113 of FIG. 1A) appears to be reduced when viewed from the outside.

Referring to FIGS. 6G - 6I, in an embodiment, a first inner portion 1132 of a first side surface member 113 may include a recessed portion 1138 formed to be lower than an outer surface 1137 of the first inner portion 1132. Although not illustrated, in an embodiment, the recessed portion 1138 may also be formed in a second inner portion (e.g., the second inner portion 1232 of FIG. 3) of a second side surface member (e.g., the second side surface member 123 of FIG. 3). Although not illustrated, in an embodiment, the recessed portion 1138 may be formed over at least a portion of a third inner portion (e.g., the third inner portion 1134a of FIG. 3) via a first bending portion (e.g., the first bending portion 1133a of FIG. 3) from one end of the first inner portion 1132 and/or over at least a portion of a fourth inner portion (e.g., the fourth inner portion 1234a of FIG. 3) via a second bending portion (e.g., the second bending portion 1233a of FIG. 3) from one end of the second inner portion (e.g., the second inner portion 1232 of FIG. 3). In addition, in another embodiment, the recessed portion 1138 may be formed over at least a portion of a fifth inner portion (e.g., the fifth inner portion 1134b of FIG. 3) via a third bending portion (e.g., the third bending portion 1133b of FIG. 3) from the other end of the first inner portion 1132 and/or over at least a portion of a sixth inner portion (e.g., the sixth inner portion 1234bof FIG. 3) via a fourth bending portion (e.g., the fourth bending portion 1233bof FIG. 3) from the other end of the second inner portion (e.g., the second inner portion 1232 of FIG. 3).

In an embodiment, the recessed portion 1138 may be formed to have a height (e.g., the length of the recessed portion 1138 in the z-axis direction) that varies starting from a point higher than or substantially equal to a top surface of the window layer 410 of the flexible display 400. For example, as illustrated in FIG. 6G, the height of the recessed portion 1138 (e.g., the length of the recessed portion 1138 in the z-axis direction) may be formed to correspond to the height from the window layer 410 of the flexible display 400 to at least a portion of the display panel 430. For example, as illustrated in FIG. 6I, the height of the recessed portion 1138 (e.g., the length of the recessed portion 1138 in the z-axis direction) may be formed to correspond to the height from the window layer 410 of the flexible display 400 to the digitizer 460.

In an embodiment, the electronic device 100 may include a protective member 636 (e.g., the first protective member 610 and/or the second protective member 620 of FIG. 3) disposed at least partially in the recessed portion 1138. In an embodiment, the protective member 636 may include a first portion 6361 disposed on an inner surface of the recessed portion 1138, a third portion 6363 disposed to be visible between the outer surface 1137 of the first inner portion 1132 and the flexible display 400 when viewed from above (e.g., in the z-axis direction), and a second portion 6362 configured to connect the first portion 6361 and the third portion 6363. In an embodiment, the first portion 6361 may be disposed over a height of the recessed portion 1138 (e.g., the length of the recessed portion 1138 in the z-axis direction) and may be disposed in a portion of a width W1 of the recessed portion 1138 (e.g., the length of the recessed portion 1138 in the y-axis direction). In an embodiment, the second portion 6362 may be disposed to correspond to a portion of the height of the recessed portion 1138. For example, the second portion 6362 may be disposed to have a height corresponding to a portion of the polarizer 420. However, the disclosure is not limited thereto, and the second portion 6362 may be formed not to correspond to layers that have relatively large interlayer slip displacement among the plurality of layers 410, 420, 430, 440, 450, and 460 constituting the flexible display 400.

In an embodiment, the width W1 of the recessed portion 1138 (e.g., the length of the recessed portion 1138 in the y-axis direction) may be configured to be greater than a width W2 of the protective member 636 (e.g., the third portion 6363) that is visible between the outer surface 1137 of the first inner portion 1132 and the flexible display 400 when viewed from above (e.g., in the z-axis direction).

In an embodiment, the electronic device 100 may be configured to protect the flexible display 400 from an external impact by including the recessed portion 1138 and the protective member 636 disposed at least partially in the recessed portion 1138, and to maintain surface quality of the flexible display 400 by configuring layers having relatively large interlayer slip displacement to be disposed in the recessed portion 1138 when the electronic device 100 is in the folded state (e.g., the second state). In addition, the electronic device 100 may be configured such that the visible width of the protective member 636, which is visually exposed when a user uses the electronic device 100, is reduced.

Referring to FIG. 6J, in an embodiment, a first inner portion 1132 of a first side surface member 113 may include a recessed region 1139 forming a curved surface recessed inward and a placement region 1140 extending from the recessed region 1139. Although not illustrated, in an embodiment, the recessed region 1139 and the placement region 1140 may also be formed in a second inner portion (e.g., the second inner portion 1232 of FIG. 3) of a second side surface member (e.g., the second side surface member 123 of FIG. 3). Although not illustrated, in an embodiment, the recessed region 1139 and the placement region 1140 may be formed over at least a portion of a third inner portion (e.g., the third inner portion 1134a of FIG. 3) via a first bending portion (e.g., the first bending portion 1133a of FIG. 3) from one end of the first inner portion 1132 and/or over at least a portion of a fourth inner portion (e.g., the fourth inner portion 1234a of FIG. 3) via a second bending portion (e.g., the second bending portion 1233a of FIG. 3) from one end of the second inner portion (e.g., the second inner portion 1232 of FIG. 3). In addition, in another embodiment, the recessed region 1139 and the placement region 1140 may be formed over at least a portion of a fifth inner portion (e.g., the fifth inner portion 1134b of FIG. 3) via a third bending portion (e.g., the third bending portion 1133b of FIG. 3) from the other end of the first inner portion 1132 and/or over at least a portion of a sixth inner portion (e.g., the sixth inner portion 1234b of FIG. 3) via a fourth bending portion (e.g., the fourth bending portion 1233b of FIG. 3) from the other end of the second inner portion (e.g., the second inner portion 1232 of FIG. 3).

In an embodiment, the recessed region 1139 may be formed to correspond to a portion of the window layer 410 and the polarizer 420 of the flexible display 400. However, the disclosure is not necessarily limited thereto, and the recessed region 1139 may be formed to correspond to layers having relatively large interlayer slip displacement among the plurality of layers 410, 420, 430, 440, 450, and 460 constituting the flexible display 400.

In an embodiment, the electronic device 100 may include a protective member 637 disposed in the placement region 1140 (e.g., the first protective member 610 and/or the second protective member 620 of FIG. 3).

In an embodiment, a width W3 of the recessed region 1139 (e.g., the length of the recessed region 1139 in the y-axis direction) may be configured to be greater than a width W2 of the protective member 637 when viewed from above (e.g., in the z-axis direction).

In an embodiment, the electronic device 100 may be configured to protect the flexible display 400 from an external impact by including the recessed region 1139 and the protective member 637 disposed at least partially in the placement region 1140, and to maintain surface quality of the flexible display 400 by configuring layers having relatively large interlayer slip displacement to be disposed in the recessed region 1138 when the electronic device 100 is in the folded state (e.g., the second state). In addition, the electronic device 100 may be configured such that the visible width of the protective member 637, which is visually exposed when a user uses the electronic device 100, is reduced.

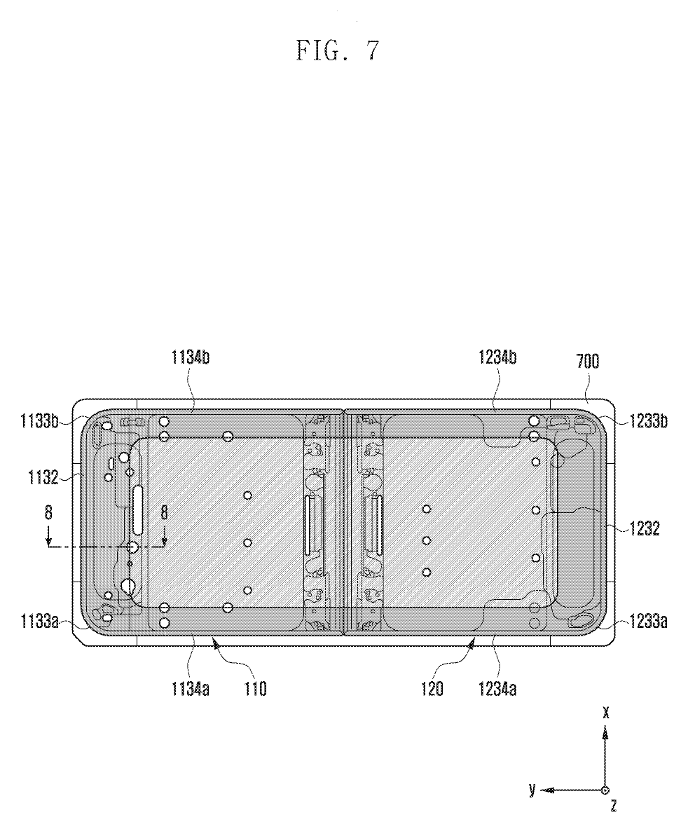

FIG. 7 is a view illustrating a state in which a dummy member is coupled to a first housing and a second housing according to an embodiment of the disclosure.

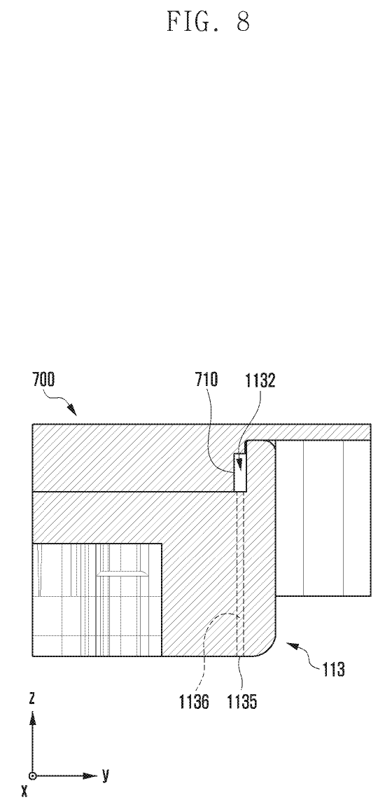

FIG. 8 is a partial cross-sectional view taken along line 8-8 of FIG. 7, according to an embodiment of the disclosure.

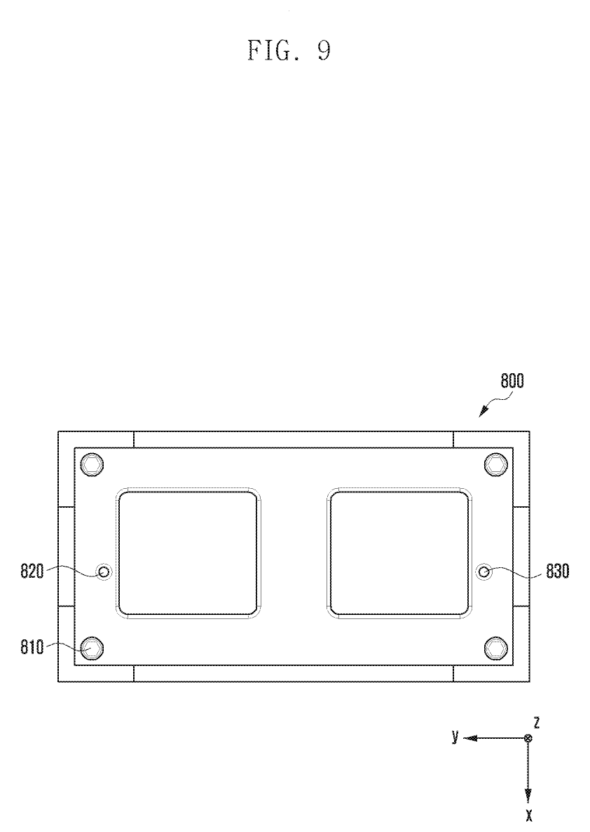

FIG. 9 is a view illustrating a state in which a first housing and a second housing, to which a dummy member is coupled, are coupled to a jig according to an embodiment of the disclosure.

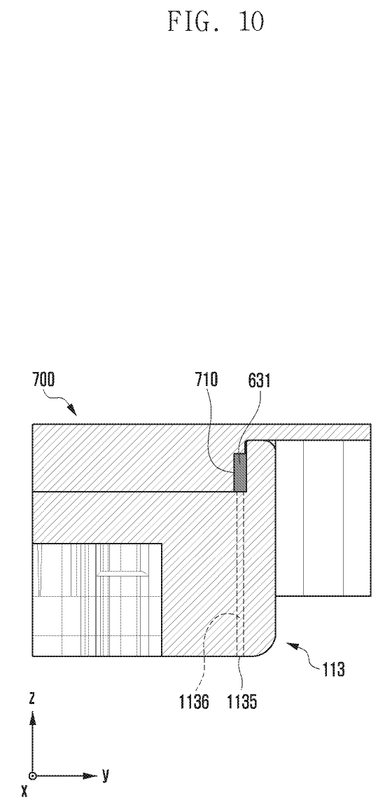

FIG. 10 is a partial cross-sectional view illustrating a state in which a filler constituting a protective member is filled, taken along line 8-8 of FIG. 7, according to an embodiment of the disclosure.

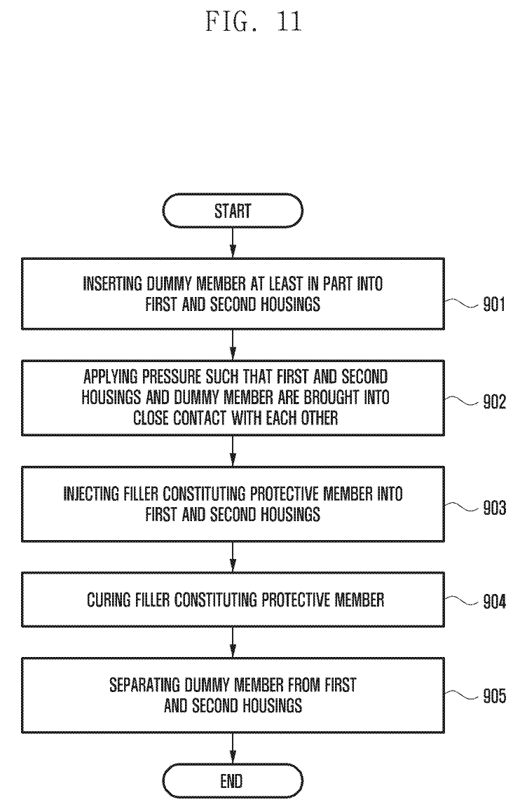

FIG. 11 is a view illustrating a process of applying a protective member to a flexible display according to an embodiment of the disclosure.

Referring to FIGS. 7 - 11, in a first process 901, a dummy member 700 may be provided. The dummy member 700 may be inserted at least in part into the first and second housings 110 and 120. Although FIGS. 8 and 10 illustrate only a state in which the dummy member 700 is inserted at least in part into the first housing 110, a state in which the dummy member 700 is inserted at least in part into the second housing 120 may be substantially the same in a symmetrical manner as illustrated in FIG. 8. In an embodiment, as illustrated in FIG. 8, the dummy member 700 may include a cavity portion 710 configured to form an empty space having a predetermined shape inside the first and second housings 110 and 120. The dummy member 700 may be inserted into the first and second housings 110 and 120, and may form, by using the cavity portion 710, an empty space corresponding to the shape of the first protective member 610 and/or the shape of the second protective member 620 in the first inner portion 1132 and/or the second inner portion 1232. Although FIGS. 8 and 10 illustrate the protective member 610 illustrated in FIG. 6A as an example, the disclosure is not limited thereto. The shape of the cavity portion 710 may be formed to correspond to shapes of protective members 631, 632, 633, 634, 635, 636, and 637 according to various embodiments illustrated in FIGS. 6B - 6F. According to various embodiments, the cavity portion 710 of the dummy member 700 may be formed to correspond to the first inner portion 1132 and/or the second inner portion 1232. In an embodiment, the cavity portion 710 may be formed to correspond to at least a portion of the third inner portion 1134a via the first bending portion 1133a from one end of the first inner portion 1132 and/or to correspond to at least a portion of the fourth inner portion 1234a via the second bending portion 1233a from one end of the second inner portion 1232. In another embodiment, the cavity portion 710 may be formed to correspond to at least a portion of the fifth inner portion 1134b via the third bending portion 1133b from the other end of the first inner portion 1132 and/or to correspond to at least a portion of the sixth inner portion 1234b via the fourth bending portion 1233b from the other end of the second inner portion 1232.

According to various embodiments, the electronic device 100 may include an injection port 1135 and a flow path 1136 formed in the second surface 112 of the first housing 110 and/or the fourth surface 122 of the second housing 120 and configured such that a filler constituting the protective members 610, 620, 631, 632, 633, 634, 635, 636, and 637 is injected toward the first inner portion 1132 and/or the second inner portion 1232.

In a second process 902, a jig 800 may be provided to apply pressure such that the first and second housings 110 and 120 and the dummy member 700 are brought into close contact with each other. The jig 800 may be configured to bring the first and second housings 110 and 120 and the dummy member 700 into close contact with each other by using at least four fastening members 810. The jig 800 may include a first jig hole 820 and/or a second jig hole 830. The first jig hole 820 may be configured to communicate with the injection port 1135 and the flow path 1136 formed in the second surface 112 of the first housing 110. The second jig hole 830 may be configured to communicate with the injection port 1135 and the flow path 1136 formed in the fourth surface 122 of the second housing 120.

In a third process 903, a filler constituting a protective member may be injected into the first and/or second housings 110 and 120. The filler constituting the protective members 610, 620, 631, 632, 633, 634, 635, 636, and 637 may be filled into at least the first inner portion 1132 via the first jig hole 820 and then via the injection port 1135 and the flow path 1136 formed in the second surface 112 of the first housing 110. In addition, the filler constituting the protective members 610, 620, 631, 632, 633, 634, 635, 636, and 637 may be filled into at least the second inner portion 1232 via the second jig hole 830 and then via the injection port 1135 and the flow path 1136 formed in the fourth surface 122 of the second housing 120. The filler constituting the protective members 610, 620, 631, 632, 633, 634, 635, 636, and 637 may be filled so as to completely fill the space formed by the cavity portion 710. The process of injecting the filler constituting the protective members 610, 620, 631, 632, 633, 634, 635, 636, and 637 may be performed in a state in which the second surface 112 of the first housing 110 and the fourth surface 122 of the second housing 120 are oriented upward. That is, the filler constituting the protective members 610, 620, 631, 632, 633, 634, 635, 636, and 637 may be injected in a state in which the injection port 1135 is oriented upward and the dummy member 700 is oriented downward. By doing so, the surfaces of the protective members 610, 620, 631, 632, 633, 634, 635, 636, and 637 may be configured to be uniformly formed.

In an embodiment, the electronic device 100 may include protective members 610, 620, 631, 632, 633, 634, 635, 636, and 637 including a thermal expansion material. In an embodiment, a filler constituting the protective members 610, 620, 631, 632, 633, 634, 635, 636, and 637 including the thermal expansion material may be injected into the first inner portion 1132 and/or the second inner portion 1232 by using a separate dummy member (not illustrated). Here, the separate dummy member may form a space having a smaller volume than a space formed by the cavity portion 710.

In a fourth process 904, the injected filler constituting the protective members 610, 620, 631, 632, 633, 634, 635, 636, and 637 may be cured to form the protective members 610, 620, 631, 632, 633, 634, 635, 636, and 637. The curing may be UV curing or thermal curing. However, the disclosure is not limited thereto. In the fourth process 904, the filler constituting the protective members 610, 620, 631, 632, 633, 634, 635, 636, and 637 may be firmly coupled to the first inner portion 1132 of the first housing 110 and/or the second inner portion 1232 of the second housing 120.

In an embodiment, the protective members 610, 620, 631, 632, 633, 634, 635, 636, and 637 including a thermal expansion material may be cured through thermal curing. The filler constituting the protective members 610, 620, 631, 632, 633, 634, 635, 636, and 637 including the thermal expansion material may expand in volume by using the cavity portion 710 of the dummy member 700 and, at the same time, may be molded into the shapes of the protective members 610, 620, 631, 632, 633, 634, 635, 636, and 637. The thermal expansion material may form pores within the protective members 610, 620, 631, 632, 633, 634, 635, 636, and 637 during the thermal curing process. In an embodiment, by including the pores, the protective members 610, 620, 631, 632, 633, 634, 635, 636, and 637 may improve low-dielectric characteristics.

In a fifth process 905, after the filler constituting the protective members 610, 620, 631, 632, 633, 634, 635, 636, and 637 is cured, the jig 800 and the dummy member 700 may be separated from the first and second housings 110 and 120.

According to various embodiments, the foldable display 400 may be disposed after completion of the fifth process 905. By forming the protective members 610, 620, 631, 632, 633, 634, 635, 636, and 637 before the foldable display 400 is disposed, damage to the foldable display 400 during a manufacturing process may be prevented, and accordingly, productivity may be improved.

According to various embodiments, an electronic device 100 may include a first housing 110, a second housing 120 coupled to the first housing 110 to be rotatable about a folding axis F by using a hinge device 140, a flexible display 400 disposed to be supported by the first housing 110 and the second housing 120 and including a plurality of layers, and protective members 610 and 620 including a first protective member 610 disposed on a first inner portion 1132 of the first housing 110 parallel to the folding axis F and a second protective member 620 disposed on a second inner portion 1232 of the second housing 120 parallel to the folding axis F. The first protective member 610 may be spaced apart from a first edge 403 of the flexible display 400 facing the first inner portion 1132 by a predetermined distance L1, and the second protective member 620 may be spaced apart from a second edge 401 of the flexible display 400 facing the second inner portion 1232 by the predetermined distance L1.

According to various embodiments, in a first state in which the flexible display 400 is fully unfolded, a distance between the first protective member 610 and the first edge 403 may be equal to the predetermined distance L1, and a distance between the second protective member 620 and the second edge 401 may be equal to the predetermined distance L1. In a second state in which the flexible display 400 is fully folded, the distance between the first protective member 610 and the first edge 403 may be smaller than the predetermined distance L1, and the distance between the second protective member 620 and the second edge 401 may be smaller than the predetermined distance L1.

According to various embodiments, the first housing 110 may include a third inner portion 1134a extending in a direction perpendicular to the first inner portion 1132 from one end of the first inner portion 1132 through a first bending portion 1133a, and the second housing 120 may include a fourth inner portion 1234a extending in a direction perpendicular to the second inner portion 1232 from one end of the second inner portion 1232 through a second bending portion 1233a. The first protective member 610 may extend from one end of the first inner portion 1132 through the first bending portion 1133a to at least a portion of the third inner portion 1134a, and the second protective member 620 may extend from one end of the second inner portion 1232 through the second bending portion 1233a to at least a portion of the fourth inner portion 1234a.

According to various embodiments, the first housing 110 may include a fifth inner portion 1134b extending in a direction perpendicular to the first inner portion 1132 from the other end of the first inner portion 1132 through a third bending portion 1133b, and the second housing 120 may include a sixth inner portion 1234b extending in a direction perpendicular to the second inner portion 1232 from the other end of the second inner portion 1232 through a fourth bending portion 1233b. The first protective member 610 may extend from the other end of the first inner portion 1132 through the third bending portion 1133b to at least a portion of the fifth inner portion 1134b, and the second protective member 620 may extend from the other end of the second inner portion 1232 through the fourth bending portion 1233b to at least a portion of the sixth inner portion 1234b.

According to various embodiments, the first protective member 610 may be disposed to have a uniform perpendicular distance from the first edge 403, and the second protective member 620 may be disposed to have a uniform perpendicular distance from the second edge 401.

According to various embodiments, a protective member 631 may have an upper edge formed in a rounded shape adjacent to the flexible display 400.

According to various embodiments, protective members 632, 633, and 634 may include a first protective surface 6321, 6331, and 6341 formed to be inclined in a direction toward the flexible display 400, and a second protective surface 6322, 6332, and 6342 extending from the first protective surface 6321, 6331, and 6341 and having a uniform perpendicular distance from the first edge 403 or the second edge 401.

According to various embodiments, the first protective surface 6341 may be planar.

According to various embodiments, the first protective surfaces 6321 and 6331 may be a curved surface protruding outward or a curved surface recessed inward.

According to various embodiments, the protective member 635 may include a first protective surface 6351 formed to be spaced apart from the flexible display 400 by a distance greater than the predetermined distance L1, and a second protective surface 6352 formed to be stepped from the first protective surface 6351 and formed to be spaced apart from the flexible display 400 by the predetermined distance L1.

According to various embodiments, each of the first housing 110 and the second housing 120 may include an injection port 1135 formed on a rear surface that is a surface opposite to a direction in which the flexible display 400 is disposed, the injection port 1135 being configured to allow injection of a filler constituting the protective member.

According to various embodiments, the first inner portion 1132 may include a recessed portion 1138 formed to be at least partially lower than an outer surface 1137 of the first inner portion 1132, and a first protective member 636 may be disposed at least partially in the recessed portion 1138.

According to various embodiments, the width of the recessed portion 1138, when viewed from above, may be greater than the width of the first protective member 636 disposed between the outer surface 1137 of the first inner portion 1132 and the flexible display 400.

According to various embodiments, the first inner portion 1132 may include a recessed region 1139 forming a surface that is a curved surface recessed inward, and a placement region 1140 extending from the recessed region 1139, and the first protective member 637 may be disposed in the placement region 1140.

According to various embodiments, the width of the recessed region 1139 may be greater than a width of the first protective member 637.

According to various embodiments, a method of manufacturing an electronic device 100 may include inserting at least a portion of a dummy member 700 including a cavity portion 710 configured to form an empty space having a predetermined shape in interiors of first and second housings 110 and 120, pressurizing the first and second housings 110 and 120 and the dummy member 700 such that the first and second housings 110 and 120 and the dummy member 700 are in close contact with each other, injecting a filler into the first and second housings 110 and 120, curing the filler to form protective members 610 and 620, and separating the dummy member 700 from the first and second housings 110 and 120. The second housing 120 may be coupled to the first housing 110 to be rotatable about a folding axis F by using a hinge device 140, the first and second housings 110 and 120 may be configured to support a flexible display 400 including a plurality of layers, and the protective members 610 and 620 may include a first protective member 610 disposed on a first inner portion 1132 of the first housing 110 parallel to the folding axis F and a second protective member 620 disposed on a second inner portion 1232 of the second housing 120 parallel to the folding axis F. The first protective member 610 may be spaced apart from a first edge 403 of the flexible display 400 by a predetermined distance L1, and the second protective member 620 may be spaced apart from a second edge 401 of the flexible display 400 by the predetermined distance L1.

According to various embodiments, the injecting of the filler into the first and second housings 110 and 120 may be performed through an injection port 1135 formed on a rear surface of each of the first and second housings 110 and 120, the rear surface being a surface opposite to a direction in which the flexible display 400 is disposed.

According to various embodiments, the injecting of the filler into the first and second housings 110 and 120 may be performed while the injection port 1135 is oriented in an upward direction.

According to various embodiments, the filler may include a thermally expandable material, and the curing of the filler may be a thermal curing process.

While the disclosure has been shown and described with reference to various embodiments thereof, it will be understood by those skilled in the art that various changes in form and details may be made therein without departing from the spirit and the scope of the disclosure as defined by the appended claims and their equivalents.

What is claimed is:

1. An electronic device comprising:
a first housing;
a second housing coupled to the first housing to be rotatable about a folding axis by using a hinge device;
a flexible display disposed to be supported by the first housing and the second housing and including a plurality of layers; and
a protective member including a first protective member disposed on a first inner portion of the first housing parallel to the folding axis, and a second protective member disposed on a second inner portion of the second housing parallel to the folding axis,
wherein the first protective member is spaced apart from a first edge of the flexible display facing the first inner portion by a predetermined distance, and
wherein the second protective member is spaced apart from a second edge of the flexible display facing the second inner portion by the predetermined distance.

2. The electronic device of claim 1,
wherein, in a first state in which the flexible display is fully unfolded, a distance between the first protective member and the first edge is equal to the predetermined distance, and a distance between the second protective member and the second edge is equal to the predetermined distance, and
wherein, in a second state in which the flexible display is fully folded, the distance between the first protective member and the first edge is smaller than the predetermined distance, and the distance between the second protective member and the second edge is smaller than the predetermined distance.

3. The electronic device of claim 1,
wherein the first housing includes a third inner portion extending in a direction perpendicular to the first inner portion from one end of the first inner portion through a first bending portion,
wherein the second housing includes a fourth inner portion extending in a direction perpendicular to the second inner portion from one end of the second inner portion through a second bending portion,
wherein the first protective member extends from the one end of the first inner portion through the first bending portion to at least a portion of the third inner portion, and
wherein the second protective member extends from the one end of the second inner portion through the second bending portion to at least a portion of the fourth inner portion.

4. The electronic device of claim 3,
wherein the first housing includes a fifth inner portion extending in a direction perpendicular to the first inner portion from an opposite end of the first inner portion through a third bending portion,
wherein the second housing includes a sixth inner portion extending in a direction perpendicular to the second inner portion from an opposite end of the second inner portion through a fourth bending portion,
wherein the first protective member extends from the opposite end of the first inner portion through the third bending portion to at least a portion of the fifth inner portion, and
wherein the second protective member extends from the opposite end of the second inner portion through the fourth bending portion to at least a portion of the sixth inner portion.

5. The electronic device of claim 1,
wherein the first protective member is disposed to have a uniform perpendicular distance from the first edge, and
wherein the second protective member is disposed to have uniform perpendicular distance from the second edge.

6. The electronic device of claim 1, wherein the protective member has an upper edge formed in a rounded shape adjacent to the flexible display.

7. The electronic device of claim 1, wherein the protective member further includes:
a first protective surface formed to be inclined in a direction toward the flexible display; and
a second protective surface extending from the first protective surface and having a uniform perpendicular distance from the first edge or the second edge.

8. The electronic device of claim 7, wherein the first protective surface is planar.

9. The electronic device of claim 7, wherein the first protective surface is a curved surface protruding outward or a curved surface recessed inward.

10. The electronic device of claim 1, wherein the protective member further includes:
a first protective surface formed to be spaced apart from the flexible display by a distance greater than the predetermined distance; and
a second protective surface formed to be stepped from the first protective surface and formed to be spaced apart from the flexible display by the predetermined distance.

11. The electronic device of claim 1, wherein each of the first housing and the second housing includes an injection port formed on a rear surface that is a surface opposite to a direction in which the flexible display is disposed, the injection port being configured to allow injection of a filler constituting the first protective members and the second protective member.

12. The electronic device of claim 1,
wherein the first inner portion includes a recessed portion formed to be at least partially lower than an outer surface thereof, and
wherein the first protective member is disposed at least partially in the recessed portion.

13. The electronic device of claim 12, wherein, when viewed from above, a width of the recessed portion is greater than a width of the first protective member disposed between the outer surface of the first inner portion and the flexible display.

14. The electronic device of claim 1,
wherein the first inner portion includes:
a recessed region forming a surface that is a curved surface recessed inward, and
a placement region extending from the recessed region, and
wherein a first protective member is disposed in the placement region.

15. The electronic device of claim 14, wherein a width of the recessed region is greater than a width of the first protective member.

16. A method of manufacturing an electronic device, the method comprising:
inserting at least a portion of a dummy member including a cavity portion configured to form an empty space having a predetermined shape in interiors of first and second housings;
pressurizing the first and second housings and the dummy member such that the first and second housings and the dummy member are in close contact with each other;
injecting a filler into the first and second housings;
curing the filler to form protective members; and
separating the dummy member from the first and second housings,
wherein the second housing is coupled to the first housing to be rotatable about a folding axis by using a hinge device,
wherein the first and second housings are configured to support a flexible display including a plurality of layers,
wherein the protective members include a first protective member disposed on a first inner portion of the first housing parallel to the folding axis, and a second protective member disposed on a second inner portion of the second housing parallel to the folding axis,
wherein the first protective member is spaced apart from a first edge of the flexible display by a predetermined distance, and
wherein the second protective member is spaced apart from a second edge of the flexible display by the predetermined distance.

17. The method of claim 16, wherein the injecting of the filler into the first and second housings is performed through an injection port formed on a rear surface of each of the first and second housings, the rear surface being a surface opposite to a direction in which the flexible display is disposed.

18. The method of claim 17, wherein the injecting of the filler into the first and second housings is performed in a state in which the injection port is oriented in an upward direction.

19. The method of claim 16,
wherein the filler includes a thermally expandable material, and
wherein the curing of the filler is a thermal curing process.

20. The method of claim 16,
wherein the first protective member is disposed to have a uniform perpendicular distance from the first edge, and
wherein the second protective member is disposed to have a uniform perpendicular distance from the second edge.

21. The method of claim 16, wherein the predetermined distance is between 0.05 mm to 0.15 mm.
